(19) United States
(12) Patent Application Publication
(10) Pub. No.: US 2014/0197387 A1
(43) Pub. Date: Jul. 17, 2014

(54) NANOCOMPOSITE, METHOD OF PREPARING THE SAME, AND SURFACE LIGHT EMITTING DEVICE USING THE SAME

(71) Applicant: Samsung Electronics Co., Ltd., Suwon-si (KR)

(72) Inventors: Hiroshi MIYAO, Yokohama (JP); Tadao YAGI, Yokohama (JP); Ryuichi SATOH, Yokohama (JP)

(73) Assignee: Samsung Electronics Co., Ltd., Suwon-si (KR)

(21) Appl. No.: 14/079,959

(22) Filed: Nov. 14, 2013

(30) Foreign Application Priority Data
Nov. 14, 2012 (JP) 2012-250504
Oct. 31, 2013 (KR) 10-2013-0131505

(51) Int. Cl. H01L 51/00; H01L 51/52

(52) U.S. Cl. CPC H01L 51/0035; H01L 51/52; H01L 51/0094
USPC 257/40; 524/600

(57) ABSTRACT

Provided is a nanocomposite including a matrix resin including a polyimide, and a surface-modified inorganic oxide nanoparticle dispersed in the matrix, wherein the surface-modified inorganic oxide nanoparticle includes an inorganic oxide nanoparticle, a first functional group modifying a surface of the inorganic oxide nanoparticle and having an imide backbone, and a second functional group modifying a surface of the inorganic oxide nanoparticle and binding to the matrix resin.

### RELATED APPLICATIONS

This application claims the benefit of Japanese Patent Application No. 2012-0250504, filed on Nov. 14, 2012, in the Japanese Patent Office and Korean Patent Application No. 10-2013-0131505, filed on Oct. 31, 2013, in the Korean Intellectual Property Office, the disclosures of which are incorporated herein in their entireties by reference.

### BACKGROUND

1. Field

The present disclosure relates to a nanocomposite, a method of preparing the same, and a surface light emitting device using the same.

2. Description of the Related Art

Organic resin materials are applied to various areas as they are easy to process. Recently, in addition to light weight and good processibility of organic resin materials, additional properties such as an electric property, mechanical strength, and optical property are required. To satisfy the electric property, mechanical strength, and optical property which may not be accomplished by conventional organic resin materials alone, various studies have been conducted by combining an inorganic material which is excellent in these properties with an organic material in order to develop a composite material which accompanies properties of both of the materials.

On the other hand, application of a composite material to optics requires inorganic particles not to be coagulated but to be dispersed in an organic resin as primary particles. In particular, for a plastic lens and a camera module, inorganic particles having a high refractive index need to be dispersed in a resin. However, particles having a high refractive index, represented by zirconium oxide and titanium oxide, are highly coagulative and the refractive index difference is great between the particles having a high refractive index with a resin in which the particles are dispersed. Thus, to prepare a material having a high refractive index and a high level of transparency, particles should not be coagulated but need to be dispersed at a nanometer level. In addition, to form a high refractive index lens with a composite material, a thick film having no cracks needs to be prepared with particles having a high refractive index at a high filling level.

Methods of dispersing inorganic particles in an organic resin include, for example, an in situ synthesis method according to a sol-gel method, a method of repressing secondary coagulation by covering a surface of mechanically dispersed nanoparticles with a dispersing agent, or a method of preventing secondary coagulation by forming a chemical bonding on a particle surface by using a silane coupling agent.

With respect to the method of repressing secondary coagulation by covering a surface of dispersed nanoparticles with a dispersing agent, for example, Japan Patent Laid-Open Publication No. 2001-164136 describes a method of dispersing metal oxide nanoparticles by adding 2-50% of appropriate dispersing agent and mixing the resulting dispersion with a polymer binder. In addition, with respect to the method of preventing secondary coagulation by forming a chemical bonding on a particle surface by using a silane coupling agent, for example, as in Japan Patent Laid-Open Publication No. 2009-298955, a method of modifying an inorganic particle surface with a backbone selected from the group consisting of a fluorene backbone, an anthracene ring, a dibenzothiophene ring, a stilbene ring, a biphenyl backbone, and a naphthalene ring through a silane coupling agent has been suggested.

In addition, with respect to the method of preventing secondary coagulation by forming a chemical bonding on a particle surface by using a silane coupling agent, for example, as in Japan Patent Laid-Open Publication No. 2011-236110, a method of modifying an inorganic particle surface with a functional group having several different organic groups has been suggested. Japan Patent Laid-Open Publication No. 2010-100061 discloses a method of preparing a composite including a linker, which has a functional group making a chemical bond with an inorganic particle or a polymer, and an organic polymer.

On the other hand, in a case where a conventional nanocomposite prepared by dispersing a nanoparticle is used as a component of an optical device, the nanocomposite is often exposed to a high temperature when a metal is deposited in a mounting process. Hence, a nanocomposite having a high heat resistance is necessary. However, most previous studies regarding a nanocomposite employed a general-purpose polymer with which deterioration of a nanocomposite in a high-temperature mounting process might have not been resolved.

Recently, to solve the problem of nanocomposite deterioration, attempts have been made to prepare a nanocomposite using a transparent polymer having a high heat resistance. Polyimide is considered as a representative polymer having a high heat resistance. Polyimide is a general name of polymers having an imide bond (—C(═O)—NR—C(═O)—) as a repeating unit in the molecular structure. A polymer having a ring-shaped imide backbone in which aromatic compounds are directly linked by an imide bond has a robust and rigid molecular structure because the aromatic compounds have a conjugate structure with each other through the imide bond. In addition, because an imide bond is highly polar and has a strong intermolecular force, the bonding between molecular chains is also rigid. Thus, among polymers, an aromatic polyimide having a ring-shaped imide backbone is often used industrially as it is very stable thermally, mechanically, and chemically and is rigid. Therefore, development of a nanocomposite material in which an inorganic particle is dispersed at a nanometer level in a polyimide is desired. In this regard, Japan Patent Laid-Open Publication No. 2001-348477 discloses a method of making a composite of a polyimide having a particular backbone, an inorganic oxide, and an inorganic sulfide.

In addition, a flat-panel display is actively developed in recent times and a representative surface light emitting device used as a light emitting device for the flat-panel display is organic light emitting diode (OLED). As an OLED has a laminated structure of materials having different refractive indices, OLED can have low light irradiation efficiency to the outside (light extraction efficiency) due to the effect of reflection on an interface. With respect to the problem, Japan Patent Laid-Open Publication No. 2010-256458 discloses a method of preparing a scattering layer to improve the light extraction efficiency.

However, as described in Japan Patent Laid-Open Publication No. 2001-164136, dispersity may be improved by covering nanoparticle surface by using an organic dispersing agent but a prepared film containing the same is deteriorated as the dispersing agent is volatilized or deteriorated by a treatment at a high temperature. In addition, as inorganic particles having a high refractive index, such as barium titanate, titanium oxide, and zirconium oxide, have a high cohesiveness themselves. Thus, uniformly dispersing the particles at a nanometer level using a conventional dispersing agent while maintaining the heat resistance was difficult.

The technology disclosed in Japan Patent Laid-Open Publication No. 2009-298955 employs an epoxy resin or an acryl resin as an organic resin and thus the technology was difficult to use to manufacture a part which requires a treatment at a high temperature. As described above, for a composite material having a heat resistance, a highly heat resistant organic resin compound needs to be used.

Japan Patent Laid-Open Publication No. 2011-236110 discloses a method of modifying an inorganic particle surface with a functional group having several different organic groups. However, to improve dispersibility of an inorganic particle, an organic group needs to be designed according to the matrix of a dispersion target. This reference includes no suggestions about the organic group design. Thus, it is difficult to uniformly disperse barium titanate, titanium oxide, and zirconium oxide, which are inorganic particles having a high refractive index, at a nanometer level using the method disclosed in this reference.

Japan Patent Laid-Open Publication No. 2010-100061 discloses a method of preparing a composite of a linker, which has a functional group making a chemical bond with an inorganic particle or a polymer, and an organic polymer. However, dispersibility of an inorganic particle was not improved by the method.

As described above, Japan Patent Laid-Open Publication No. 2001-348477 discloses a method of mixing a polyimide with an inorganic nanoparticle. However, according to the considerations of the inventors, this reference does not disclose a particular method of dispersing a nanoparticle. It was also found that dispersing of an inorganic particle in a polyimide having a strong intermolecular force by a general method (e.g. the method disclosed in Japan Patent Laid-Open Publication No. 2001-164136) did not improve the dispersibility at a nanometer level as the particle was coagulated by an interaction between an inorganic particle and a polyimide.

As described above, it was difficult to uniformly disperse barium titanate, titanium oxide, and zirconium oxide, which are inorganic particles having a high refractive index, at a nanometer level by using a conventional dispersing agent while maintaining the heat resistance. In addition, a method to specifically improve the dispersibility of polyimide, which has a strong intermolecular force and a high heat resistance, has not been suggested until now. In addition, a technology to repress a crack which may be generated during film thickening has never been suggested.

In addition, Japan Patent Laid-Open Publication No. 2010-256458 does not mention a refractive index of a matrix. As the refractive index of conventional organic matrices is 1.6 or lower, the conventional organic matrices might have not filled the refractive index gap between a matrix and a transparent oxide thin film or a light emitting layer and thus sufficient improvement in light extraction efficiency was not obtained even by scattering the light.

### SUMMARY

An aspect of the present disclosure is for resolution of the problems described above. An aspect of the present disclosure provides a high refractive index nanocomposite having excellent heat resistance and transparency and allowing for repression of a crack generation during film thickening, a method of preparing the same, and a surface light emitting device wherein the light emitting performance is improved by using the nanocomposite.

Other aspects are described in detail below.

### BRIEF DESCRIPTION OF THE DRAWINGS

These and/or other aspects will become apparent and more readily appreciated from the following description of the embodiments, taken in conjunction with the accompanying drawings in which:

FIG. 1 shows the composition of a nanocomposite according to an embodiment;

FIG. 2 shows the structure of a surface-modified inorganic oxide nanoparticle according to an embodiment;

FIG. 3 shows an interaction and a chemical boding between a surface-modified inorganic oxide nanoparticle and a matrix resin;

FIG. 4 shows an example of a mechanism by which an amino group is introduced to a surface of an inorganic oxide nanoparticle;

FIG. 5 shows an example of a mechanism by which an epoxy group is introduced to a surface of an inorganic oxide nanoparticle;

FIG. 6 shows the cross sectional composition of a surface light emitting device according to an embodiment of the present disclosure;

FIG. 7 shows the cross sectional composition of a surface light emitting device according to an embodiment;

FIG. 8 shows the cross sectional composition of a surface light emitting device according to an embodiment;

FIG. 9A is an optical microscope image of the nanocomposite film of Example 1 and FIG. 9B is an optical microscope image of the nanocomposite film of Comparative Example 4; and

FIG. 10 is a graph showing the measured refractive index (635 nanometers) of the nanocomposite films vs. the filling ratio (volume percent) of the oxide nanoparticles.

### DETAILED DESCRIPTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. The term “or” means “and/or.” Expressions such as “at least one of,” when preceding a list of elements, modify the entire list of elements and do not modify the individual elements of the list. It will be understood that when an element is referred to as being “on” another element, it can be directly in contact with the other element or intervening elements may be present therebetween. In contrast, when an element is referred to as being “directly on” another element, there are no intervening elements present. As used herein, the singular forms “a,” “an,” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

An aspect of the present disclosure to resolve the problems described above provides a nanocomposite including a matrix resin including a polyimide; and a surface-modified inorganic oxide nanoparticle including an inorganic oxide nanoparticle, a first functional group modifying a surface of the inorganic oxide nanoparticle and having an imide backbone, and a second functional group modifying a surface of the inorganic oxide nanoparticle and binding to the matrix resin and being dispersed in the matrix resin.

A nanoparticle according to the aspect of the present disclosure has excellent heat resistance due to including a matrix resin including polyimide. In addition, as the surface of the inorganic oxide nanoparticle is modified with a first functional group having an imide backbone, the inorganic oxide nanoparticle is uniformly distributed to the matrix resin. Thus, the transparency of the nanoparticle is improved. In addition, as the surface of the inorganic oxide nanoparticle is modified with a second functional group, the inorganic oxide nanoparticle is tightly bound to the matrix resin. Thus, generation of a crack at thick film is repressed. In other words, as crack generation and transparency decrease are repressed even after including a great quantity of inorganic oxide nanoparticle in the nanocomposite, a great quantity of inorganic oxide nanoparticle may be included in the nanocomposite and the refractive index of the nanocomposite is further increased.

The second functional group may have an epoxy group.

According to the aspect of the present disclosure, as the second functional group has an epoxy group the nanoparticle may be tightly bound to the matrix resin.

The volume percentage of the inorganic oxide nanoparticle to the total nanocomposite may be 30 vol % or higher.

According to the aspect of the present disclosure, as the nanocomposite includes 30 vol % or higher of the inorganic oxide nanoparticle, the refractive index is increased. However, in this case also, the transparency is increased and the crack generation during film thinking is repressed. For example, the nanocomposite may include 30-60 vol % of the inorganic oxide nanoparticle.

In addition, the mean particle diameter of the inorganic oxide nanoparticle by direct observation method may be between 2 nm and 100 nm.

According to the aspect of the present disclosure, as the mean particle diameter of the inorganic oxide nanoparticle by direct observation method is between 2 nm and 100 nm, a secondary coagulation of the inorganic oxide nanoparticle is repressed and the transparency of the nanocomposite is further improved.

In addition, the inorganic oxide nanoparticle may include titanium oxide, zirconium oxide, or barium titanate.

According to the aspect of the present disclosure, as the inorganic oxide nanoparticle include titanium oxide, zirconium oxide, or barium titanate, the nanocomposite is easily prepared to have a high refractive index.

In addition, the inorganic oxide nanoparticle may include a rutile-type titanium oxide.

According to the aspect of the present disclosure, the inorganic oxide nanoparticle includes a rutile titanium oxide, the nanocomposite is easily prepared to have a high refractive index.

Another aspect of the present disclosure provides a method of preparing a nanocomposite including modifying a surface of an inorganic oxide nanoparticle with a silane coupling agent having an amino group, represented by General Formula 1 below, or a phosphate ester compound having an amino group, represented by General Formula 2 below, imidizing at least a portion of the amino groups to produce an inorganic oxide nanoparticle having a surface modified with a first functional group having an imide backbone, modifying the surface of the inorganic oxide nanoparticle with a second functional group having epoxy group to obtain a surface-modified inorganic oxide nanoparticle including the inorganic oxide nanoparticle and a first functional group and a second functional group modifying the surface of the inorganic oxide nanoparticle, and mixing the surface-modified inorganic oxide nanoparticle with a polyamic acid and treating with heat the resulting mixture of the surface-modified inorganic oxide nanoparticle and the polyamic acid.

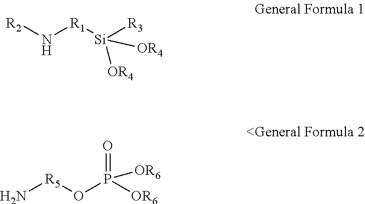

In General Formula 1 above, R₁ may be a substituted or unsubstituted C1 through C10 alkylene group, a substituted or unsubstituted C6 through C20 arylene group, or a substituted or unsubstituted C4 through C20 heteroarylene group, R₂ may be a hydrogen atom or a substituted or unsubstituted C1 through C10 alkyl group, R₃ may be a substituted or unsubstituted C1 through C10 alkyl group or a substituted or unsubstituted C1 through C10 alkoxy group, and R₄ may be a substituted or unsubstituted C1 through C10 alkyl group.

In General Formula 2 above, R₅ may be a substituted or unsubstituted C1 through C10 alkylene group, a substituted or unsubstituted C6 through C20 arylene group, a substituted or unsubstituted C4 through C20 heteroarylene group, or a substituted or unsubstituted C4 through C20 aryloxy group, and R₆ may be a substituted or unsubstituted C1 through C10 alkyl group.

The substitution group of “substituted or unsubstituted” may include a deuterium, a halogen atom, C1 through C10 alkyl group, a carboxyl group, a cyano group, or an amino group.

According to this aspect of the present disclosure, after binding a silane coupling agent or a phosphate ester compound to a surface of an inorganic oxide nanoparticle, an amino group of the silane coupling agent or a phosphate ester compound is imidized. And then, the surface of the inorganic oxide nanoparticle is modified with a second functional group. Thus, the surface of the inorganic oxide nanoparticle may be modified more definitely and more easily.

Another aspect of the present disclosure provides a method of preparing a nanocomposite including imidizing at least a portion of amino groups included in a silane coupling agent, represented by General Formula 1 below, or a phosphate ester compound, represented by General Formula 2 below, to obtain a silane coupling agent or a phosphate ester compound having an imide backbone, binding the silane coupling agent or the phosphate ester compound having an imide backbone to a surface of an inorganic oxide nanoparticle to obtain an inorganic oxide nanoparticle having a surface modified with a first functional group having an imide backbone, modifying the surface of the inorganic oxide nanoparticle with a second functional group having an epoxy group to obtain a surface-modified inorganic oxide nanoparticle comprising the inorganic oxide nanoparticle and a first functional group and a second functional group modifying the surface of the inorganic oxide nanoparticle, and mixing the surface-modified inorganic oxide nanoparticle with a polyamic acid and treating with heat the resulting mixture of the surface-modified inorganic oxide nanoparticle and the polyamic acid.

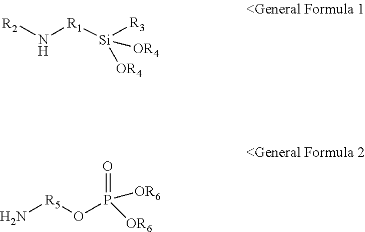

R₁ to R₆ are described above.

According to this aspect of the present disclosure, an amino group included in a silane coupling agent or a phosphate ester compound is imidized in advance and then the imidized silane coupling agent or the phosphate ester compound is bound to a surface of the inorganic oxide nanoparticle. And then, the surface of the inorganic oxide nanoparticle is modified with the second functional group. Thus, the surface of the inorganic oxide nanoparticle may be modified more definitely and more easily.

Another aspect of the present disclosure provides a method of preparing a nanocomposite including modifying a surface of an inorganic oxide nanoparticle with a silane coupling agent having an amino group, represented by General Formula 1 below, or a phosphate ester compound having an amino group, represented by General Formula 2 below, imidizing at least a portion of the amino groups to produce an inorganic oxide nanoparticle having a surface modified with a first functional group having an imide backbone, modifying the surface of the inorganic oxide nanoparticle with a second functional group having an epoxy group to produce a surface-modified inorganic oxide nanoparticle having the inorganic oxide nanoparticle and a first functional group and a second functional group modifying the surface of the inorganic oxide nanoparticle, mixing the surface-modified inorganic oxide nanoparticle with a diamine and an acid dianhydride and reacting the diamine and the acid dianhydride to produce a mixture of the surface-modified inorganic oxide nanoparticle and a polyamic acid, and treating with heat the resulting mixture.

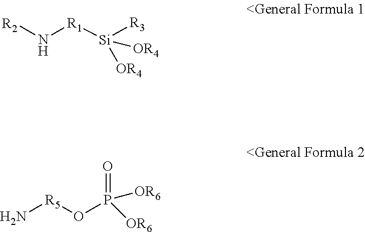

R₁ to R₆ are described above.

According to this aspect of the present disclosure, as a nanocomposite is prepared by the so-called “in situ synthesis,” coagulation of the inorganic oxide nanoparticle may be repressed during the preparation of the nanocomposite.

Another aspect of the present disclosure provides a method of preparing a nanocomposite including imidizing at least a portion of amino groups included in a silane coupling agent represented by General Formula 1 below or a phosphate ester compound represented by General Formula 2 below to obtain a silane coupling agent or a phosphate ester compound having an imide backbone, binding the silane coupling agent or the phosphate ester compound having an imide backbone to a surface of an inorganic oxide nanoparticle to obtain an inorganic oxide nanoparticle having a surface modified with a first functional group having an imide backbone, modifying the surface of the inorganic oxide nanoparticle with a second functional group having an epoxy group to obtain a surface-modified inorganic oxide nanoparticle having a first functional group and a second functional group modifying the inorganic oxide nanoparticle and the surface of the inorganic oxide nanoparticle, mixing the surface-modified inorganic oxide nanoparticle with a diamine and an acid dianhydride and reacting the diamine and the acid dianhydride to produce a mixture of the surface-modified inorganic oxide nanoparticle and a polyamic acid, and treating the resulting mixture with heat.

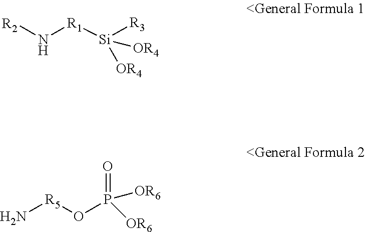

R₁ to R₆ are described above.

According to this aspect of the present disclosure, as a nanocomposite is prepared by the so-called “in situ synthesis,” coagulation of the inorganic oxide nanoparticle may be repressed during the preparation of the nanocomposite.

Another aspect of the present disclosure provides a surface light emitting device employing a translucent substrate wherein a transparent substrate of the translucent substrate is covered by a covering layer including the nanocomposite, a transparent conductive film laminated on the translucent substrate, and an organic electroluminescent layer laminated on the transparent conductive film.

As the surface light emitting device according to this aspect of the present disclosure has the nanocomposite, the electric power efficiency, which is the light emitting efficiency, is improved.

The translucent substrate may employ a transparent substrate having an embossed surface and a covering layer covering the embossed surface of the transparent substrate.

According to this aspect of the present disclosure, as a light emitting angle may be changed by the embossed surface of the transparent substrate, light may be extracted to the outside of the device (into the air).

In addition, the covering layer may include the nanocomposite and a scattering particle dispersed in the nanocomposite and the translucent substrate may employ a transparent substrate having a flat surface and the covering layer covering the flat surface of the transparent substrate.

According to this aspect of the present disclosure, as a light emitting angle may be converted by the scattering particle, light may be extracted to the outside of the device (into the air).

In addition, the translucent substrate may employ a transparent substrate having an embossed surface and a covering layer covering the embossed surface and the covering layer may include the nanocomposite and a scattering particle dispersed in the nanocomposite.

According to this aspect of the present disclosure, as a light emitting angle may be changed by the scattering particle and the embossed surface of the transparent substrate, light may be extracted to the outside of the device (into the air).

The inventors considered a method of uniformly dispersing a high refractive index inorganic oxide nanoparticle in a polyimide or a polyamic acid having high heat resistance at a nanometer level and found that modifying a surface of a high refractive index inorganic oxide nanoparticle with a first functional group having an imide backbone specifically improves the dispersibility in a polyimide. The inventors also found that, after modifying the surface of the high refractive index inorganic oxide nanoparticle with the functional group NO. 1 having an imide backbone, a silane coupling agent having an epoxy group is bound to the surface of the inorganic oxide nanoparticle. According to this method, crack generation is repressed during thickening of a film wherein a matrix resin is filled with the inorganic oxide nanoparticle.

1. Composition of Nanocomposite

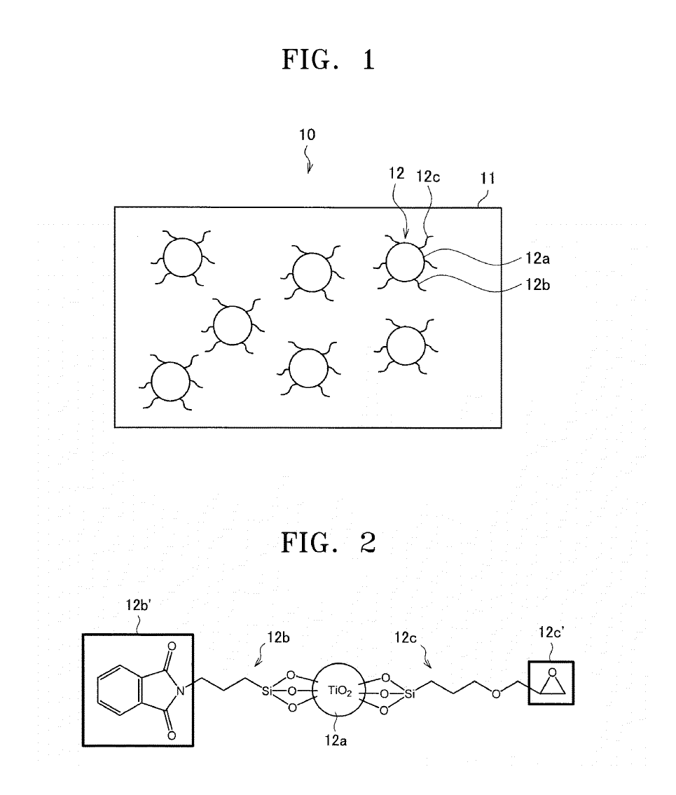

Firstly, referring to FIG. 1, the composition of the nanocomposite according to an aspect of the present disclosure is described. FIG. 1 illustrates the composition of the nanocomposite according to an aspect of the present disclosure. A nanocomposite generally refers to a composite material prepared by dispersing 1-100 nanometer (nm) size particles of a material in another material. The components and the physical properties of the nanocomposite provided by an aspect of the present disclosure are described hereinafter.

1.1 Components of Nanocomposite

As illustrated in FIG. 1, the nanocomposite (10) according to an aspect of the present disclosure is prepared by dispersing in a matrix resin (11) an inorganic oxide nanoparticle (12) of which surface is modified by functional groups.

Matrix Resin (11)

Matrix resin (11), which is a component of the nanocomposite (10), includes a polyimide. A polyimide generally refers to a material having an imide backbone (—C(═O)—NR—C(═O)), for example, represented by General Formula 3 and General Formula 4 below. When an optical application (e.g., a surface light emitting device such as an organic electroluminescent device) is considered, using a polyimide having a high transparency and a high refractive index as a matrix resin is important (11). In addition, in the view of heat resistance or chemical stability, an aromatic polyimide having a ring-shaped imide backbone, in which aromatic compounds are directly linked by an imide bond, is appropriate. In other words, although R₇ and R₈ in General Formula 3 and General Formula 4 below may be an arbitrary organic group, an organic group including an aromatic ring is appropriate. R₇ in General Formula 3 and General Formula 4 below may be independent with each other and R₈ in General Formula 3 and General Formula 4 below may be independent with each other, too. A specific example of R₇ and R₈ may be derived from specific compounds of a diamine in General Formula 5 and of a dianhydride in General Formula 6 below.

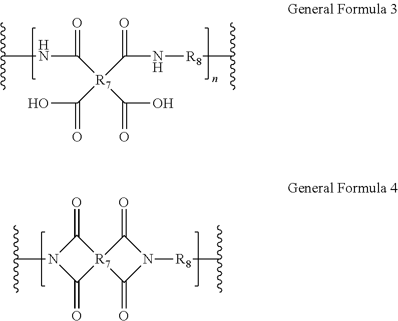

A polyimide is a polymer obtained by copolymerizing monomers which are a diamine represented by General Formula 5 and a dianhydride represented by General Formula 6 below. As the monomers which are a diamine and a dianhydride may be selected from an extensive group of compounds, a polyimide molecule may be designed and various polyimides may be synthesized according to uses.

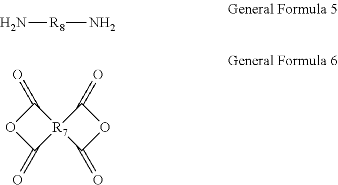

Specific examples of R₇ and R₈ in General Formula 5 and General Formula 6 above are the same as the specific examples of R₇ and R₈ in General Formula 3 and General Formula 4.

Use of the nanocomposite is not particularly limited according to an embodiment of the present disclosure, considering optical uses such as a surface light emitting including an organic luminescence device, a high refractive polyimide having a high transparency and heat resistance is appropriate to be used as the matrix resin (11).

A diamine, which is a monomer used as a raw material of a polyimide used in an embodiment of the present disclosure according to an aspect of the present disclosure, is not particularly limited, but a diamine having an aromatic ring is appropriate. As a diamine, for example, p-phenylenediamine, m-phenylenediamine, 2,4-diaminotoluene, 2,6-diaminotoluene, benzidine, o-tolidine, m-tolidine, bis-(trifluoromethyl)benzidine, octafluorobenzidine, 3,3′-dihydroxy-4,4′-diaminobiphenyl, 3,3′-dimethoxy-4,4′-diaminobiphenyl, 3,3′-dichloro-4,4′-diaminobiphenyl, 3,3′-difluoro-4,4′-diaminobiphenyl, 2,6-diaminonaphthalene, 1,5-diaminonaphthalene, 4,4′-diaminophenylether, 3,4′-diaminophenylether, 4,4′-diaminophenylmethane, 4,4′-diaminophenylsulfone, 3,4′-diaminophenylsulfone, 4,4′-diaminobenzophenone, 2,2-bis(4-(4-aminophenoxy)phenyl)propane, 2,2-bis(4-(2-methyl-4-aminophenoxy)phenyl)propane, 2,2-bis(4-(2,6-dimethyl-4-aminophenoxy)phenyl)propane, 2,2-bis(4-(4-aminophenoxy)phenyl)hexafluoropropane, 2,2-bis(4-(2-methyl-4-aminophenoxy)phenyl)hexafluoropropane, 4,4′-bis(4-aminophenoxy)biphenyl, 4,4′-bis(2-methyl-4-aminophenoxy)biphenyl, 4,4′-bis(2,6-dimethyl-4-aminophenoxy)biphenyl, 4,4′-bis(3-aminophenoxy)biphenyl, bis(4-(4-aminophenoxy)phenyl)sulfone, bis(4-(2-methyl-4-aminophenoxy)phenyl)sulfone, bis(4-(2,6-dimethyl-4-aminophenoxy)phenyl)sulfone, bis(4-(4-aminophenoxy)phenyl)ether, bis(4-(2-methyl-4-aminophenoxy)phenyl)ether, bis(4-(2,6-dimethyl-4-aminophenoxy)phenyl)ether, 1,4-bis(4-aminophenoxy)benzene, 1,4-bis(2-methyl-4-aminophenoxy)benzene, 1,4-bis(2,6-dimethyl-4-aminophenoxy)benzene, 1,3-bis(4-aminophenoxy)benzene, 1,3-bis(2-methyl-4-aminophenoxy)benzene, 1,3-bis(2,6-dimethyl-4-aminophenoxy)benzene, 2,2-bis(4-aminophenyl)propane, 2,2-bis(2-methyl-4-aminophenyl)propane, 2,2-bis(2,6-dimethyl-4-aminophenyl)propane, 2,2-bis(4-aminophenyl)hexafluoropropane, 2,2-bis(2-methyl-4-aminophenyl)hexafluoropropane, 2,2-bis(2,6-dimethyl-4-aminophenyl)hexafluoropropane, α,α′-bis(4-aminophenyl)-1,4-diisopropylbenzene, α,α-bis(2,6-dimethyl-4-aminophenyl)-1,4-diisopropylbenzene, α,α′-bis(3-aminophenyl)-1,4-diisopropylbenzene, α,α′-bis(4-aminophenyl)-1,3-diisopropylbenzene, α,α′-bis(2-methyl-4-aminophenyl)-1,3-diisopropylbenzene, α,α′-bis(2,6-dimethyl-4-aminophenyl)-1,3-diisopropylbenzene, α,α′-bis(3-aminophenyl)-1,3-diisopropylbenzene, 9,9-bis(4-aminophenyl)fluorene, 9,9-bis(2-methyl-4-aminophenyl)fluorene, 9,9-bis(2,6-dimethyl-4-aminophenyl)fluorene, 1,1-bis(4-aminophenyl)cyclopentane, 1,1-bis(2-methyl-4-aminophenyl)cyclopentane, 1,1-bis(2,6-dimethyl-4-aminophenyl)cyclopentane, 1,1-bis(4-aminophenyl)cyclohexane, 1,1-bis(2-methyl-4-aminophenyl)cyclohexane, 1,1-bis(2,6-dimethyl-4-aminophenyl)cyclohexane, 1,1-bis(4-aminophenyl)-4-methyl-cyclohexane, 1,1-bis(4-aminophenyl)norbornene, 1,1-bis(2-methyl-4-aminophenyl)norbornene, 1,1-bis(2,6-dimethyl-4-aminophenyl)norbornene, 1,1-bis(4-aminophenyl)adamantine, 1-bis(2-methyl-4-aminophenyl)adamantine, 1,1-bis(2,6-dimethyl-4-aminophenyl)adamantine, or 2,2′-bis(trifluoromethyl)benzidine may be used. However, in order to express a high transparency with a high refractive index material, it is effective to have an aromatic ring in the polyimide molecule and, to introduce a functional group providing asymmetry in the molecule, such as (—O— or —SO₂—). From this it is appropriate to use bis(3-aminophenyl)sulfone etc. which includes a sulfur atom.

In addition, a dianhydride is not particularly limited, but a dianhydride having an aromatic ring may be preferably used. As a dianhydride, pyromellitic acid dianhydride, 3,3,4,4-biphenyltetracarboxylic acid dianhydride, 2,3,3′,4′-biphenyltetracarboxylic acid dianhydride, 2,2-bis(3,4-dicarboxyphenyl)propane dianhydride, 2,2-bis(2,3-dicarboxyphenyl)propane dianhydride, 2,2-bis(3,4-dicarboxyphenyl)-1,1,1,3,3,3-hexafluoropropane dianhydride, 2,2-bis(2,3-dicarboxyphenyl)-1,1,1,3,3,3-hexafluoropropane dianhydride, bis(3,4-dicarboxyphenyl)sulfone dianhydride, bis(3,4-dicarboxyphenyl)ether dianhydride, bis(2,3-dicarboxyphenyl)ether dianhydride, 4-(2,5-dioxotetrahydrofuran-3-yl)-1,2,3,4-tetrahydronaphthalene-1,2-dicarboylic acid dianhydride, 3,3′,4,4′-benzophenone tetracarboxylic acid dianhydride, 2,2′,3,3′-benzophenone tetracarboxylic acid dianhydride, 4,4′-(p-phenylenedioxy)diphthalic acid dianhydride, 4,4′-(m-phenylenedioxy)diphthalic acid, ethylene tetracarboxylic acid dianhydride, 3-carboxymethyl-1,2,4-cyclopentane tricarboxylic acid dianhydride, 1,1-bis(2,3-dicarboxyphenyl)ethane dianhydride, bis(2,3-dicarboxyphenyl)methane dianhydride, bis(3,4-dicarboxyphenyl)methane dianhydride, or 4,4′-(hexafluoroisopropylidene)diphthalic acid dianhydride may be used.

These diamines and dianhydride may be used alone or as a combination of two or more species.

In addition, besides the diamines or dianhydride described above as a raw material of a polyimide or a polyamic acid, as a component which may improve adhesiveness to a device material to an extent not to reduce a refractive index or transparency, a diamine of silicone or a diamine or an anhydride including an alkali or an acid in a side chain may be used. Specifically, as a diamine including a silicone, KF8010, X-22-161 A, or X-22-161 B (ShinEtsu Silicones) and, as a diamine including an alkyl group in a side chain, 4,4′-diamino-3-dodecyldiphenylether or 1-octadecanoxy-2,4-diaminobenzene may be used.

Surface-Modified Inorganic Oxide Nanoparticle (12)

A surface-modified inorganic oxide nanoparticle (12), which is a component of the nanocomposite (10), has an inorganic oxide nanoparticle (12a), a first functional group (12b), and a second functional group (12c). An inorganic oxide nanoparticle (12a) is not particularly limited, and, for example, zirconium oxide, yttria-added zirconium oxide, lead zirconic acid, strontium titanic acid, tin titanic acid, tin oxide, bismuth oxide, niobium oxide, tantalum oxide, potassium tantalic acid, tungsten oxide, cerium oxide, lanthanum oxide, gallium oxide, silica, alumina, titanium oxide, and barium titanic acid may be used. Among them, to use a nanocomposite for an optical purpose, it is appropriate to use titanium oxide, barium titanic acid (refractive index=2.4), or zirconium oxide (refractive index=2.1) having a high refractive index as an inorganic oxide nanoparticle (12a). Titanium oxide usually has two types of crystal structure, which are a rutile type and an anatase type. As the anatase type of titanium oxide has a high photocatalytic activity, it may not be appropriate for an optical use. Among the inorganic oxide nanoparticles mentioned above, the rutile type titanium oxide has the highest refractive index and has a low photocatalytic activity and thus it may be preferably used as the inorganic oxide nanoparticle (12a). In addition, to reduce the photocatalytic activity of titanium oxide, a titanium oxide particle of which surface is coated with silica may be used.

In addition, an inorganic oxide nanoparticle of which mean particle diameter is in a range from about 2 nm to about 100 nm may be used. An inorganic oxide nanoparticle of which mean particle diameter is smaller than 2 nm may cause a secondary coagulation and whiten a film coated with the nanocomposite (10). In addition, it is difficult to obtain a particle having a high crystallinity by using an inorganic oxide nanoparticle of which the mean particle diameter is smaller than 2 nm. On the other hand, when the mean particle diameter is greater than 100 nm, as uniformity of the film coated with the nanocomposite (10) is not achieved because of the excessively great particle diameter, the coated film may not be transparent and an optically transparent composite may not be obtained due to increased light scattering. A mean particle diameter in an embodiment of the present disclosure refers to the number average particle diameter of primary particles. In addition, as a method of measuring the mean diameter the inorganic oxide nanoparticle, to directly measure the diameter of primary particles, TEM is used to observe directly. With respect to the nanocomposite of the present disclosure, as described above, a primary particle diameter of the inorganic oxide nanoparticle in the range from about 2 nm to about 100 nm is appropriate. However, even when the primary particle diameter is in this range, an inorganic oxide nanoparticle which is not well dispersed in a matrix resin may be coagulated with each other. In such a state, a secondary particle diameter measured by dynamic light scattering method, by which a particle diameter of a secondary particle formed by coagulation of primary particles is also measured, may be extremely large. In other words, a particle diameter measured by dynamic light scattering method may be referred to as an indicator showing whether particles are well dispersed or not. For example, when a particle diameter measured by dynamic light scattering method is 100 nm or smaller, the state of particle dispersion may be appropriate. When a mean particle diameter is greater than 100 nm, it is difficult to obtain an optically transparent nanocomposite as light scattering is too high.

A range in which crystallinity or particle diameter of an inorganic particle is controlled is greatly dependent on synthetic method. As a synthetic method of the inorganic oxide nanoparticle (12a), for example, a liquid phase synthesis method including a metal alkoxide synthetic method (sol-gel method) and a hydrothermal synthetic method may be used. In a metal alkoxide synthetic method, a metal alkoxide including that of barium or titanium is hydrolyzed and undergoes a condensation polymerization reaction by dealcoholization or dehydration to produce a metal oxide. In addition, by adjusting composition of a solvent used in the condensation polymerization reaction, water concentration at the time of polymerization initiation, or reaction temperature, the particle diameter of the inorganic oxide nanoparticle (12a) may be controlled. Crystallinity of the inorganic oxide nanoparticle (12a) is higher when the reaction temperature is high, and an amorphous particle is easily synthesized as a low temperature. In addition, in a hydrothermal synthetic method, an oxide nanoparticle may be synthesized under high temperature and high pressure conditions in a closed system. While an oxide nanoparticle may be synthesized at a relatively low temperature by a hydrothermal synthetic method, as the reaction time is long, operation cost may be high and the product purity may be lower than that of a metal alkoxide synthetic method. Thus, using a metal alkoxide synthetic method may be appropriate.

In addition, the surface of the inorganic oxide nanoparticle (12a) according to an embodiment of the present disclosure is modified with first functional group (12b), and second functional group (12c) having an imide backbone. FIG. 2 shows a specific example. In the specific example shown in FIG. 2, the inorganic oxide nanoparticle (12a) is titanium oxide.

As shown in FIG. 2, the surface of the inorganic oxide nanoparticle (12a) is modified with first functional group (12b) having an imide backbone shown in a box (12b′) in FIG. 2. As the inorganic oxide nanoparticle (12a) has an imide backbone on the surface, the inorganic oxide nanoparticle (12a) is stabilized by an interaction between the imide backbone on the surface of inorganic oxide nanoparticle (12a) and the imide backbone in a polyimide used for the matrix resin (11).

In addition, the surface of the inorganic oxide nanoparticle (12a) is modified with a second functional group (12c). The second functional group (12c) is combined with the matrix resin (11). Specifically, the second functional group (12c) has an epoxy group in a box 12c′ in FIG. 2 and, as the epoxy group is combined with a carboxylic acid group of a polyamic acid which is a precursor of the matrix resin (11), the inorganic oxide nanoparticle (12a) is combined with the matrix resin (11).

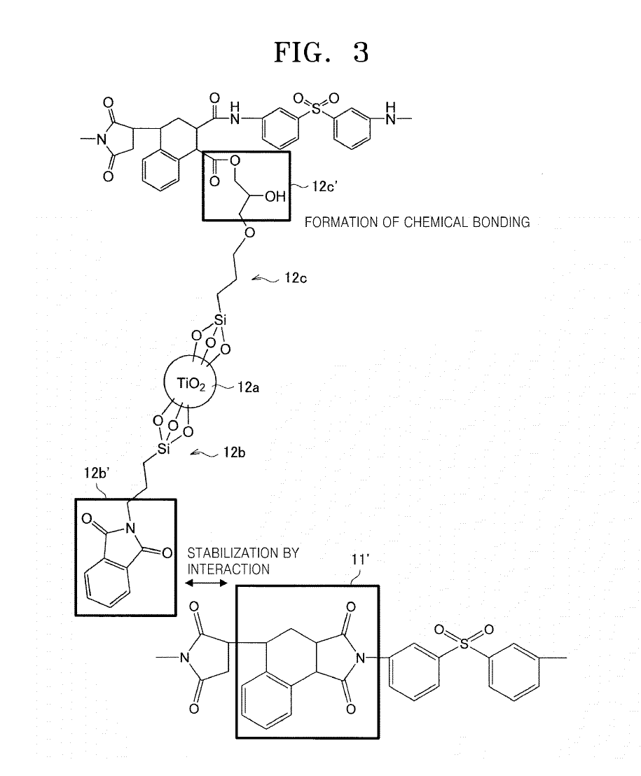

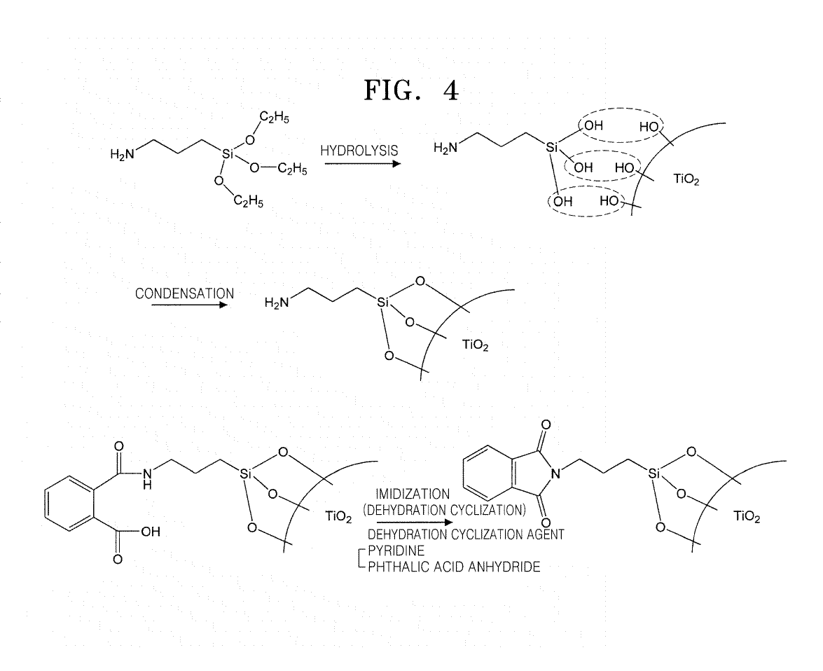

The function of the surface-modified inorganic oxide nanoparticle (12) is explained herein by referring to FIG. 3. FIG. 3 is a diagram explaining the interaction and the chemical bond between the surface-modified inorganic oxide nanoparticle (12) and the matrix resin (11).

As shown in FIG. 3, the surface of the inorganic oxide nanoparticle (12a) is modified with the first functional group (12b) having an imide backbone shown in a box (12b′) in FIG. 3. As the inorganic oxide nanoparticle (12a) has an imide backbone on the surface, the inorganic oxide nanoparticle (12a) is stabilized by an interaction between the imide backbone on the surface of inorganic oxide nanoparticle (12a) and the imide backbone in a polyimide used for the matrix resin (11, box in FIG. 3). In other words, compatibility between the matrix resin (11) and the inorganic oxide nanoparticle (12a) is increased. Thus, the surface-modified inorganic oxide nanoparticle (12) which is formed by modifying the surface of the inorganic oxide nanoparticle (12a) with a functional group having an imide backbone may selectively improve dispersity with respect to a polyimide.

In other words, by modifying the surface of the inorganic oxide nanoparticle (12a) with the first functional group (12b) having an imide backbone, the affinity of the inorganic oxide nanoparticle (12a) with a polyimide (and a polyamic acid which is a precursor of a polyimide) is improved and coagulation of the inorganic oxide nanoparticle (12a) is effectively repressed. Without being bound by theory, the reason why the affinity of the inorganic oxide nanoparticle (12a) with a polyimide is increased may be as follows. As an imide backbone is introduced to the surface of the inorganic oxide nanoparticle (12a), an imide carbonyl oxygen on the surface of the inorganic oxide nanoparticle (12a) forms a hydrogen bond with a hydrogen of an amide bond and a carboxylic acid in a polyamic acid which is a precursor of a polyimide to improve the affinity between the inorganic oxide nanoparticle (12a) and the polyamic acid.

In addition, it is presumed that, as the first functional group (12b) has a benzene ring (a phenyl group) in the imide backbone, a stacking or a charge-transfer interaction occurs between the inorganic oxide nanoparticle (12a) and the benzene ring of a polyimide or a polyamic acid to repress coagulation of the inorganic oxide nanoparticle (12a).

Surface modification with the first functional group (12b) is performed, for example, as follows. First, the surface of the inorganic oxide nanoparticle (12a) is treated with a silane coupling agent or a phosphate ester compound having an amino group. By the surface treatment, an amino group is introduced to the surface of the inorganic oxide nanoparticle (12a). The amino group is imidized by treating the amino group with an acid anhydride. By this, the surface of the inorganic oxide nanoparticle (12a) is modified with the first functional group (12b). A detailed explanation of the surface treatment method and the specific examples of the silane coupling agent or the phosphate ester compound having an amino group are described later.

In addition, the surface of the inorganic oxide nanoparticle (12a) according to an embodiment of the present disclosure is modified with the second functional group (12c). The second functional group (12c) is combined with the matrix resin (11). Specifically, the second functional group (12c) has an epoxy group in a box 12c′ in FIG. 3 and, as the epoxy group is combined with a carboxylic acid group of a polyamic acid which is a precursor of the matrix resin (11), the inorganic oxide nanoparticle (12a) is combined with the matrix resin (11) (Refer to the part surrounded by a box 12c′ in FIG. 3.). As the inorganic oxide nanoparticle (12a) is tightly bound through the inorganic oxide nanoparticle (12a) to the matrix resin (11), crack generation during film thickening is repressed.

In addition, surface modification with the second functional group (12c) is performed by treating the surface of the inorganic oxide nanoparticle (12a) with silane coupling agent or a phosphate ester compound having an epoxy group. A detailed explanation of the surface treatment method and the specific examples of the silane coupling agent or the phosphate ester compound having an epoxy group are described later.

1.2 Physical Properties of Nanocomposite

The nanocomposite (10) according to an embodiment of the present disclosure may have physical properties of (A)-(D).

(A) The refractive index is 1.7 or higher.

(B) The haze value is 10% or lower.

(C) A film prepared in 1 μm of thickness has a total light transmittance of 80% or higher.

(D) A film of the nanocomposite (10) prepared in a particle filling ratio of 30 vol % or higher and a 5 μm of thickness has no crack.

Refractive Index

The nanocomposite (10) needs to have a high refractive index to be applied for an optical purpose and, specifically, an appropriate refractive index of the nanocomposite (10) is 1.7 or higher. In the nanocomposite (10), the inorganic oxide nanoparticle (12a) having a high refractive index is dispersed in the matrix resin (11) and the matrix resin (11) may be designed to have a high refractive index, the refractive index of the nanocomposite (10) may be 1.7 or higher.

The refractive index of the nanocomposite (10) may be controlled by controlling a filling ratio of the inorganic oxide nanoparticle (12a) in the matrix resin (11). An appropriate filling ratio of the inorganic oxide nanoparticle (12a) is dependent on composition of a polyimide used for the matrix resin (11) and the filling ratio of the inorganic oxide nanoparticle (12a) may be adjusted to have an appropriate refractive index according to the composition of the used polyimide. The particle filling ratio (filling ratio) is the volumetric percentage of the inorganic oxide nanoparticle (12a) to the total volume of the nanocomposite (10). On the other hand, by increasing the filling ratio of the inorganic oxide nanoparticle (12a), the refractive index of the nanocomposite (10) may be increased. However, as the filling ratio of the inorganic oxide nanoparticle (12a) is too high, the film property is reduced. Thus, filling ratio of the inorganic oxide nanoparticle (12a) may be preferably determined by considering a balance between the refractive index and the particle dispersity. A filling ratio is not specifically regulated. However, closet packed spherical nanoparticles have a filling ratio of \sqrt{2}/6×100 (≈74) % (wherein “≈” means “approximately equal to”) and thus the actual filling ratio of the inorganic oxide nanoparticle (12a) is lower than that. An appropriate filling ratio the inorganic oxide nanoparticle (12a) according to an embodiment of the present disclosure may be in the range from about 5% to about 70%, and more preferably, from about 10% to about 65%. When the filling ratio of the inorganic oxide nanoparticle (12a) is 5% or lower, adding the inorganic oxide nanoparticle (12a) has no effect. In addition, when the When the filling ratio of the inorganic oxide nanoparticle (12a) is 70% or higher, preparing of a film may be difficult as the ratio of an organic resin component is too small.

Transparency

To apply the nanocomposite (10) to an optical use, the nanocomposite (10) needs to have a high transparency. For the nanocomposite (10) to have a high transparency, the transparency of the matrix resin (11) needs to be high and the dispersity of the inorganic oxide nanoparticle (12a) needs to be high. As described above, because the surface of the inorganic oxide nanoparticle (12a) is modified with first functional group (12b) having an imide backbone, the dispersity of the inorganic oxide nanoparticle (12a) may be selectively increased by an interaction with a polyimide used for the matrix resin (11). In this way, a high transparency of the nanocomposite (10) may be accomplished. Specifically, in an embodiment of the present disclosure, as an index of transparency, a haze value and a total light transmittance of a film prepared in 1 μm thickness are used. In an embodiment of the present disclosure, an appropriate haze value is 10% or lower, and an appropriate total light transmittance of a film prepared in 1 μm thickness is 80%. For example, a haze value of the nanocomposite (10) may be from about 0.1% to about 10% or from about 1% to about 10% and a total light transmittance of a film prepared in 1 μm thickness may be from about 80% to about 95% or from about 80% to about 90%.

In an embodiment of the present disclosure, a haze value is a numerical value of the ratio (percentage) of the transmitted light which is not perpendicular to the film to the total transmitted light of the incident light perpendicular to a film prepared with the nanocomposite (10). A haze value and a total light transmittance may be easily measured by using a transmittance meter having an integrating sphere or a haze meter.

Discussion of Transparency

The reason why the nanocomposite (10) needs to have a high transparency is explained herein. Light transmittance is decreased when light passes through an interface with another layer due to the difference in the refractive index between layers. The degree of light transmittance decrease is determined by the refractive index of the materials and the correction during measurement. Light transmittance is calculated by Equation 1 when the measurement is performed in a resin alone or by Equation 2 when the measurement is performed on a glass substrate.

$$\begin{matrix}Light transmittance ( \% ) = \{ ( 1 - \frac{{( {n}_{1} - 1.0 )}^{2}}{{( {n}_{1} + 1.0 )}^{2}} - \frac{{( {n}_{1} - 1.0 )}^{2}}{{( {n}_{1} + 1.0 )}^{2}} ) \times F \} \times 100 & Equation 1 \\ Light transmittance ( \% ) = \{ ( 1 - \frac{{( {n}_{g} - 1.0 )}^{2}}{{( {n}_{g} + 1.0 )}^{2}} - \frac{{( {n}_{1} - {n}_{g} )}^{2}}{{( {n}_{1} + {n}_{g} )}^{2}} - \frac{{( {n}_{1} - 1.0 )}^{2}}{{( {n}_{1} + 1.0 )}^{2}} ) \times F \} \times 100 & Equation 2\end{matrix}$$

In Equations 1 and 2, n₁ denotes the refractive index of the nanocomposite (10), n_{g} denotes the refractive index of glass, and F denotes a factor representing a light damping ratio as light passes through a resin. According to the Equations, as the refractive index is increased, the refractive index difference is increased at each interface and thus the transmittance is decreased. Thus, to obtain a high transmittance, the nanocomposite (10) itself needs to have a high transparency. In particular, in an embodiment of the present disclosure, as the nanocomposite (10) is applied to a surface light emitting device, the nanocomposite (10) having a high transparency may improve the transmittance of the whole surface light emitting device.

Heat Resistance

To apply the nanocomposite (10) to an optical use, as the nanocomposite (10) is exposed to a high temperature in a mounting process, the nanocomposite (10) needs to have high heat resistance. For the nanocomposite (10) to have high heat resistance, the matrix resin (11) itself needs to have high heat resistance. In this point of view, in an embodiment of the present disclosure, a polyimide having high resistance is used as the matrix resin (11).

Crack Resistance

As described above, when a high refractive index lens is formed with the nanocomposite (10), a high refractive index particle needs to be filled into the nanocomposite (10) at a high filling ratio and a crack generation during film thickening needs to be repressed. In this point of view, in an embodiment of the present disclosure, the matrix resin (11) is combined with the inorganic oxide nanoparticle (12a) through the second functional group (12c). In this way, in an embodiment of the present disclosure, a crack generation is repressed when a film is prepared in 30 vol % or higher of particle filling ratio and 5 μm of film thickness. Existence of a crack may be verified by observation using an optical microscope.

1.3 Method of Verifying Nanocomposite Structure

Verifying whether the surface of the inorganic oxide nanoparticle (12a) is actually modified with an imide backbone may be performed by using an analytical instrument such as thermogravimetry/differential thermal analysis (TG/DTA) or FT-IR. Specifically, when the TG/DTA is used, the weight difference between an inorganic oxide nanoparticle (12a) of which surface is not modified and an inorganic oxide nanoparticle (12a) of which surface is modified with an imide group by the method mentioned above is measured at a temperature (for example, 350° C.) and the surface modification of the inorganic oxide nanoparticle (12a) may be verified from the fact that the weight of the inorganic oxide nanoparticle (12a) of which surface is modified is greater than that of the inorganic oxide nanoparticle (12a) of which surface is not modified. When FT-IR is used, observation of a C—N stretching vibration of an imide ring at a wavelength around 1390 cm⁻¹ verifies that the surface of the inorganic oxide nanoparticle (12a) is modified with a surface modifier having an imide backbone.

Modification of surface of the inorganic oxide nanoparticle (12a) with an epoxy group may be also modified by using an analytical instrument such as TG/DTA or FT-IR. Specifically, when the TG/DTA is used, the weight difference between an inorganic oxide nanoparticle (12a) of which surface is modified with the first functional group (12b) and an inorganic oxide nanoparticle (12a) of which surface is modified both with the first functional group (12b) and second functional group (12c), which is the surface-modified inorganic oxide nanoparticle (12) is measured at a temperature (for example, 350° C.). The surface modification of the inorganic oxide nanoparticle (12a) with second functional group (12c) may be verified from the fact that the weight of the surface-modified inorganic oxide nanoparticle (12) is greater than that of the inorganic oxide nanoparticle (12a) of which surface is modified with the first functional group (12b). When FT-IR is used, observation of a C-0 stretching vibration of an epoxy group at a wavelength around 925-899 cm⁻¹ verifies that the surface of the inorganic oxide nanoparticle (12a) is modified with second functional group (12c).

In addition, whether the surface-modified inorganic oxide nanoparticle (12) is dispersed in a polyimide may be verified by using dynamic light scattering method and, in addition, simply by observing the nanocomposite (10) by using TEM.

2. Method of Preparing Nanocomposite

Composition of the nanocomposite (10) according to an embodiment of the present disclosure is above described in detail. Subsequently, a method of preparing the nanocomposite (10) having the composition described above is hereinafter described in detail. A method of modifying the surface of the inorganic oxide nanoparticle (12) and a method of preparing the nanocomposite (10) are described in order.

Firstly, before describing the method of modifying the surface of the inorganic oxide nanoparticle (12), an outline of the raw materials used for the preparing of the nanocomposite (10) according to an embodiment of the present disclosure is described.

As in the nanocomposite (10) according to an embodiment of the present disclosure, preparing the nanocomposite (10) having a refractive index of 1.7 or higher only with organic components was difficult unless certain limited types of resins having a sulfur atom, a benzene ring, or a naphthalene ring were used. Thus, to extend choices of the matrix resin (11) and to prepare the nanocomposite (10) having a high refractive index at the same time, an inorganic oxide particle having a high refractive index needs to be included in an organic component. In addition, a base (matrix) organic component (polyimide) having a high refractive index may also increase the refractive index effectively, using an acid anhydride or a diamine having an aromatic backbone and a sulfur atom as the polyimide structure is appropriate.

In addition, as a haze value and a total light transmittance are dependent on film transparency and scattering, to make the haze value and the total light transmittance satisfy the conditions described above, an inorganic particle having a high refractive index needs to be dispersed in the matrix resin (11). Therefore, in an embodiment of the present disclosure, as an inorganic particle having a high refractive index, the inorganic oxide nanoparticle (12a) having a particle diameter of a nanometer order of magnitude is used.

Hereinafter, a method of preparing the nanocomposite (10) is described in detail.

2.1 Method of Modifying Surface of Inorganic Oxide Nanoparticle

Surface Modification Method NO. 1

The surface of the inorganic oxide nanoparticle (12a) may be modified by two methods. First, the surface modification method NO. 1 is described. The surface modification method NO. 1 includes binding a silane coupling agent, etc., having an amino group to the surface of the inorganic oxide nanoparticle (12a), imidizing of the amino group, and binding a silane coupling agent having an epoxy group to the surface of the inorganic oxide nanoparticle (12a).

Specifically, as described above, the surface of the synthesized inorganic oxide nanoparticle (12a) is treated with a silane coupling agent or a phosphate ester compound having an amino group to introduce an amino group to the inorganic oxide nanoparticle (12a). To introduce an amino group to the inorganic oxide nanoparticle (12a), a silane coupling agent having an amino group, represented by General Formula 1 below, or a phosphate ester compound having an amino group, represented by General Formula 2 below, is used. While a silane coupling agent itself may become an oligomer by a self-condensation reaction, a phosphate ester does not undergo a self-condensation reaction. Thus, it is assumed that a phosphate ester forms a coordinate bond with the inorganic oxide nanoparticle (12a) as a single layer.

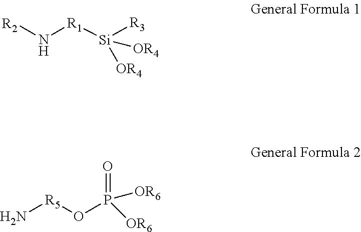

In General Formula 1 above, R₁ may be a substituted or unsubstituted C1 through C10 alkylene group, a substituted or unsubstituted C6 through C20 arylene group, or a substituted or unsubstituted C4 through C20 heteroarylene group, R₂ may be a hydrogen atom or a substituted or unsubstituted C1 through C10 alkyl group, R₃ may be a substituted or unsubstituted C1 through C10 alkyl group or a substituted or unsubstituted C1 through C10 alkoxy group, and R₄ may be a substituted or unsubstituted C1 through C10 alkyl group.

In General Formula 2 above, R₅ may be a substituted or unsubstituted C1 through C10 alkylene group, a substituted or unsubstituted C6 through C20 arylene group, a substituted or unsubstituted C4 through C20 heteroarylene group, or a substituted or unsubstituted C4 through C20 aryloxy group, and R₆ may be a substituted or unsubstituted C1 through C10 alkyl group.

The substitution group of “substituted or unsubstituted” may include a deuterium, a halogen atom, C1 through C10 alkyl group, a carboxyl group, a cyano group, or an amino group.

The used silane coupling agent with amino group is not particularly limited as long as it is represented by General Formula 1, but, for example, aminopropyltrimethoxysilane, aminopropyltriethoxysilane, N-2-(aminoethyl)-3-aminopropylmethyldimethoxysilane, N-2-(aminoethyl)-3-aminopropyltrimethoxysilane, or N-2-(aminoethyl)-3-aminopropyltriethoxysilane may be preferably used. Among them, aminopropyltrimethoxysilane and aminopropyltriethoxysilane may be preferably used.

As a phosphate ester compound having an amino group, a compound represented by General Formula 2 may be used. For example, o-phosphorylethanolamine or 5-phosphoribosylamine may be used as such a compound.

The method of modifying an inorganic oxide nanoparticle using a silane coupling agent or a phosphate ester compound is a method which has been attempted since before. For example, when a silane coupling agent having a polar group such as an amino group at the terminal is used, the hydrogen of NH₂ forms a hydrogen bonding with an OH group of a polyimide or the surface of an inorganic oxide nanoparticle. As a result, the interaction of an inorganic oxide nanoparticle with the polyimide or with another inorganic oxide nanoparticle becomes so strong that the inorganic oxide nanoparticle is easily coagulated. In addition, a technique to use a silane coupling agent or a dispersing agent having a long organic molecular chain is available to repress coagulation by increasing the distance between particles, but, as the heat resistance is decreased by the increased organic component ratio, film deterioration may occur in a treatment process at a high temperature.

Therefore, to prepare the nanocomposite (10) which is resistant to a high temperature treatment and has a high dispersity in a polyimide, in an embodiment of the present disclosure, a technique to treat an amino group with an acid anhydride and add an appropriate condensation polymerization agent is employed to imidize the amino group part. By this technique, an imide group used to modify the surface of the inorganic oxide nanoparticle (12a) and the compatibility with a polyimide was increased. As a result, the particle coagulation was repressed so that the inorganic oxide nanoparticle (12a) could be uniformly distributed in a solvent at a nanometer level. In a previously used method of use a polyamic acid or a polyimide having silicon atoms at the two terminals to coat an inorganic nanoparticle, as a polyamic acid itself has a strong intermolecular force which enhances coagulation between particles, an inorganic oxide nanoparticle could not be dispersed at a nanometer level. On the contrary, in an embodiment of the present disclosure, as the inorganic oxide nanoparticle (12a) is imidized after coating the surface with a silane coupling agent having an amino group or a phosphate ester compound having an amino group, an imidization reaction is performed one-to-one with the amino group on the particle surface so that production of extra polymer component causing particle coagulation may be prevented.

The acid anhydride used for the imidization may be, for example, maleic acid anhydride, succinic acid anhydride, phthalic acid anhydride, tetrahydrophthalic acid anhydride, or glutaric acid anhydride. To further improve dispersity in an aromatic polyimide having high heat resistance, using an acid anhydride having an aromatic ring is appropriate. In this point of view, phthalic acid anhydride is preferably used.

As described above, after modifying the surface of the inorganic oxide nanoparticle (12a) with a silane coupling agent having an amino group, represented by General Formula 1 above, or a phosphate ester compound having an amino group, represented by General Formula 2 above, at least a portion of the amino group is imidized to obtain the inorganic oxide nanoparticle (12a) of which surface is modified with the first functional group (12b) having an imide backbone.

Referring to FIG. 4, the modification mechanism by which the first functional group (12b) having an imide backbone is introduced to the surface of the inorganic oxide nanoparticle (12a) is described herein. FIG. 4 shows the mechanism by which an amino group is introduced to the surface of the inorganic oxide nanoparticle (12a) and the mechanism by which an amino group is imidized. The mechanisms are described herein by taking an example in which a titanium oxide (TiO₂) particle is used as the inorganic oxide nanoparticle (12a), 3-aminopropyltrimethoxysilane (APTES) is used as a silane coupling agent to introduce an amino group to the surface of the inorganic oxide nanoparticle (12a), and phthalic acid anhydride is used as an acid anhydride to imidize the amino group introduced to the surface of the inorganic oxide nanoparticle (12a).

Firstly, as shown in FIG. 4, as a silane coupling agent (APTES) is condensed by a hydrolysis with a hydroxyl group on the surface of the inorganic oxide nanoparticle (12a) (titanium oxide particle), an amino group is introduced to the surface of the inorganic oxide nanoparticle (12a).

Next, imidization of the amino group introduced to the surface of the inorganic oxide nanoparticle (12a) is performed by undergoing two reactions shown in FIG. 4. First, an acid anhydride (phthalic acid anhydride) undergoes an addition reaction with an amino group on the surface of the inorganic oxide nanoparticle (12a) modified with the silane coupling agent (APTES) so that the amino group may generate an amide acid (N-propylamide acid (NPPAA)). Subsequently, as the generated amide acid is chemically imidized by using a dehydration cyclization agent (phthalic acid anhydride and pyridine) to introduce an imide backbone (N-propylphthalimide (NPPI) in this example) to the surface of the inorganic oxide nanoparticle (12a). The phthalic acid anhydride serves not only as a raw material of phthalimide which reacts with an amino group on the particle surface but also as a dehydration cyclization agent causing imidization together with pyridine.

Surface Modification Method NO. 2

The surface modification method NO. 2 is a method of imidizing a silane coupling agent having an amino acid group in advance and then combining it with the inorganic oxide nanoparticle (12a). Specifically, the surface modification method NO. 2 includes imidizing a silane coupling agent having an amino group, binding the imidized silane coupling agent to the surface of the inorganic oxide nanoparticle (12a), and binding a silane coupling agent having an epoxy group to the surface of the inorganic oxide nanoparticle (12a).

In the surface modification method NO. 2 also, besides a silane coupling agent, a phosphate ester compound may be used. The imidization may be performed by using an acid anhydride the same as in the surface modification method NO. 1.

Method of Introducing Epoxy Group

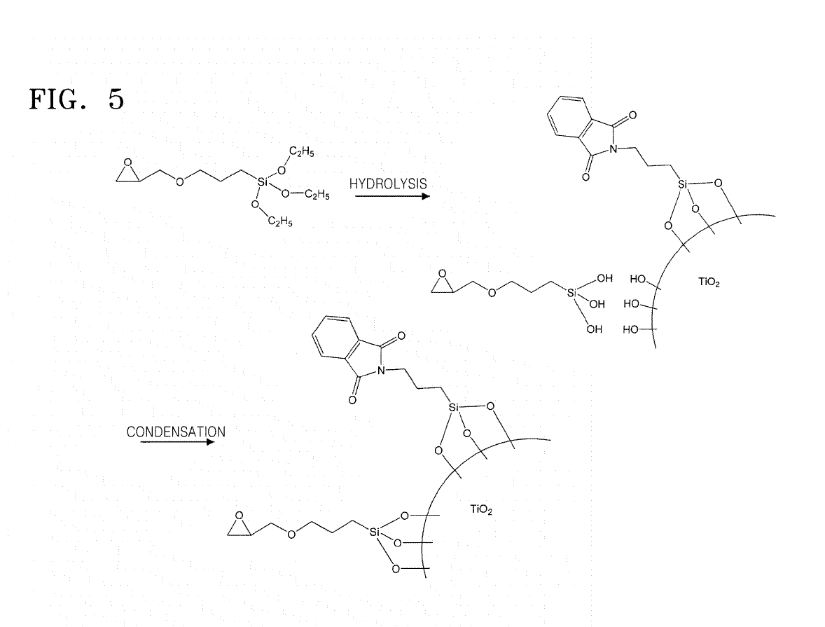

In an embodiment of the present disclosure, the second functional group (12c) is additionally introduced to the surface of the inorganic oxide nanoparticle (12a) to which the first functional group (12b) has been introduced. Hereinafter, based on FIG. 5, a method of introducing the second functional group (12c) to the surface of the inorganic oxide nanoparticle (12a) is described. In the example shown in FIG. 5, 3-glycidoxypropyltriethoxysilane is used as a silane coupling agent. In other words, by hydrolyzing the silane coupling agent which is 3-glycidoxypropyltriethoxysilane, an alkoxy group of the silane coupling agent may be converted to an hydroxyl group and, by performing a condensation polymerization of the hydroxyl group with a hydroxyl group of the inorganic oxide nanoparticle (12a), second functional group (12c) which is an epoxy group, may be introduced to the surface of the inorganic oxide nanoparticle (12a).

A silane coupling agent having an epoxy group is not particularly limited as long as it is formed by substituting the amino group in General Formula 1 with an epoxy group, but, for example, diethoxy(3-glycidyloxypropyl)methylsilane, diethoxy(3-glycidyloxypropyl)ethylsilane, 3-glycidyloxypropyltrimethoxysilane, 3-glycidyloxypropyltriethoxysilane, 3-glycidyloxypropyl(dimethoxy)methylsilane, 3-glycidyloxypropyl(diethoxy)ethylsilane, 2-(3,4-epoxycyclohexyl)ethyltrimethoxysilane, or 2-(3,4-epoxycyclohexyl)ethyltriethoxysilane may be preferably used.

2.2 Method of Synthesizing Polyimide

A method of synthesizing a polyimide used for the matrix resin (11) is not particularly limited but it may include a two-step synthesis method in which a polyimide is synthesized by passing through a precursor which is a polyamic acid and a one-step synthesis method in which a polyimide is synthesized without passing through a polyamic acid. Among these two methods, the two-step synthesis method is preferably used in an industrial point of view. The two-step synthesis method provides an advantage that imidization may be performed only by heating to 250° C. or a higher temperature. In addition, part of the obtained polyamic acid may be imidized by chemically performing a condensation polymerization reaction with acetic acid anhydride or pyridine. The two-step synthesis method and the one-step synthesis method are described in detail below.

Two-Step Synthesis Method

A two-step synthesis method is a method of synthesizing a polyimide (PI) by synthesizing a polyamic acid (PAA) having an excellent solubility in an organic solvent and an excellent processibility and then imidizing the PAA. PAA may be obtained, as shown in Reaction Formula 1 below, by mixing a diamine, represented by General Formula 5 above, which serves as a monomer of PAA in an aprotic organic solvent, with an acid dianhydride represented by General Formula 6 above. To avoid a contact with atmospheric moisture and oxygen, in nitrogen atmosphere, the monomers are dissolved in the solvent in order and a PAA is conveniently synthesized by stirring the resulting mixture at room temperature for a long period of time (for example, about 15 hours).

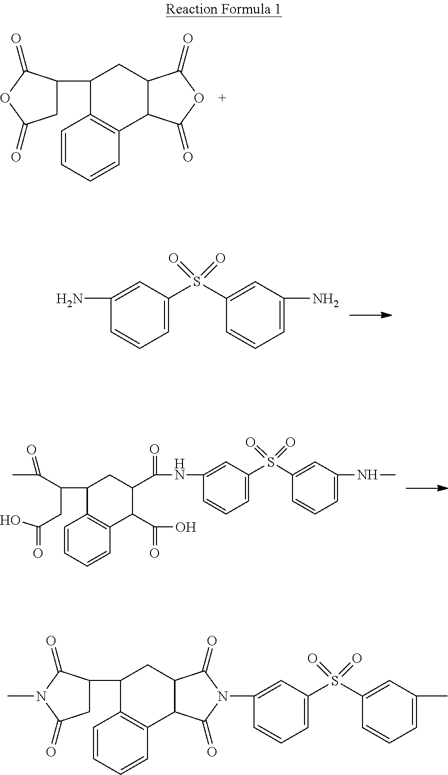

A diamine used for the synthesis is not particularly limited but a diamine having an aromatic ring is appropriate. As a diamine, for example, p-phenylenediamine, m-phenylenediamine, 2,4-diaminotoluene, 2,6-diaminotoluene, benzidine, o-tolidine, m-tolidine, bis-(trifluoromethyl)benzidine, octafluorobenzidine, 3,3′-dihydroxy-4,4′-diaminobiphenyl, 3,3′-dimethoxy-4,4′-diaminobiphenyl, 3,3′-dichloro-4,4′-diaminobiphenyl, 3,3′-difluoro-4,4′-diaminobiphenyl, 2,6-diaminonaphthalene, 1,5-diaminonaphthalene, 4,4′-diaminophenylether, 3,4′-diaminophenylether, 4,4′-diaminophenymethane, 4,4′-diaminophenylsulfone, 3,4′-diaminophenylsulfone, 4,4′-diaminobenzophenone, 2,2-bis(4-(4-aminophenoxy)phenyl)propane, 2,2-bis(4-(2-methyl-4-aminophenoxy)phenyl)propane, 2,2-bis(4-(2,6-dimethyl-4-aminophenoxy)phenyl)propane, 2,2-bis(4-(4-aminophenoxy)phenyl)hexafluoropropane, 2,2-bis(4-(2-methyl-4-aminophenoxy)phenyl)hexafluoropropane, 4,4′-bis(4-aminophenoxy)biphenyl, 4,4′-bis(2-methyl-4-aminophenoxy)biphenyl, 4,4′-bis(2,6-dimethyl-4-aminophenoxy)biphenyl, 4,4′-bis(3-aminophenoxy)biphenyl, bis(4-(4-aminophenoxy)phenyl)sulfone, bis(4-(2-methyl-4-aminophenoxy)phenyl)sulfone, bis(4-(2,6-dimethyl-4-aminophenoxy)phenyl)sulfone, bis(4-(4-aminophenoxy)phenyl)ether, bis(4-(2-methyl-4-aminophenoxy)phenyl)ether, bis(4-(2,6-dimethyl-4-aminophenoxy)phenyl)ether, 1,4-bis(4-aminophenoxy)benzene, 1,4-bis(2-methyl-4-aminophenoxy)benzene, 1,4-bis(2,6-dimethyl-4-aminophenoxy)benzene, 1,3-bis(4-aminophenoxy)benzene, 1,3-bis(2-methyl-4-aminophenoxy)benzene, 1,3-bis(2,6-dimethyl-4-aminophenoxy)benzene, 2,2-bis(4-aminophenyl)propane, 2,2-bis(2-methyl-4-aminophenyl)propane, 2,2-bis(2,6-dimethyl-4-aminophenyl)propane, 2,2-bis(4-aminophenyl)hexafluoropropane, 2,2-bis(2-methyl-4-aminophenyl)hexafluoropropane, 2,2-bis(2,6-dimethyl-4-aminophenyl)hexafluoropropane, α,α′-bis(4-aminophenyl)-1,4-diisopropylbenzene, α,α-bis(2,6-dimethyl-4-aminophenyl)-1,4-diisopropylbenzene, α,α′-bis(3-aminophenyl)-1,4-diisopropylbenzene, α,α′-bis(4-aminophenyl)-1,3-diisopropylbenzene, α,α′-bis(2-methyl-4-aminophenyl)-1,3-diisopropylbenzene, α,α′-bis(2,6-dimethyl-4-aminophenyl)-1,3-diisopropylbenzene, α,α′-bis(3-aminophenyl)-1,3-diisopropylbenzene, 9,9-bis(4-aminophenyl)fluorene, 9,9-bis(2-methyl-4-aminophenyl)fluorene, 9,9-bis(2,6-dimethyl-4-aminophenyl)fluorene, 1,1-bis(4-aminophenyl)cyclopentane, 1,1-bis(2-methyl-4-aminophenyl)cyclopentane, 1,1-bis(2,6-dimethyl-4-aminophenyl)cyclopentane, 1,1-bis(4-aminophenyl)cyclohexane, 1,1-bis(2-methyl-4-aminophenyl)cyclohexane, 1,1-bis(2,6-dimethyl-4-aminophenyl)cyclohexane, 1,1-bis(4-aminophenyl)-4-methyl-cyclohexane, 1,1-bis(4-aminophenyl)norbornene, 1,1-bis(2-methyl-4-aminophenyl)norbornene, 1,1-bis(2,6-dimethyl-4-aminophenyl)norbornene, 1,1-bis(4-aminophenyl)adamantine, 1-bis(2-methyl-4-aminophenyl)adamantine, 1,1-bis(2,6-dimethyl-4-aminophenyl)adamantine, or 2,2′-bis(trifluoromethyl)benzidine may be used. However, in order to express a high transparency with a high refractive index material, it is effective to have an aromatic ring in the polyimide molecule and, to introduce a functional group providing asymmetry in the molecule, such as (—O— or —SO₂—). From this it is appropriate to use bis(3-aminophenyl)sulfone etc. which includes a sulfur atom.

In addition, a dianhydride is not particularly limited, but a dianhydride having an aromatic ring may be preferably used. As a dianhydride, if it is a dianhydride having an aromatic ring, a dianhydride is not limited, and for example, pyromellitic acid dianhydride, 3,3,4,4-biphenyltetracarboxylic acid dianhydride, 2,3,3′,4′-biphenyltetracarboxylic acid dianhydride, 2,2-bis(3,4-dicarboxyphenyl)propane dianhydride, 2,2-bis(2,3-dicarboxyphenyl)propane dianhydride, 2,2-bis(3,4-dicarboxyphenyl)-1,1,1,3,3,3-hexafluoropropane dianhydride, 2,2-bis(2,3-dicarboxyphenyl)-1,1,1,3,3,3-hexafluoropropane dianhydride, bis(3,4-dicarboxyphenyl)sulfone dianhydride, bis(3,4-dicarboxyphenyl)ether dianhydride, bis(2,3-dicarboxyphenyl)ether dianhydride, 4-(2,5-dioxotetrahydrofuran-3-yl)-1,2,3,4-tetrahydronaphthalene-1,2-dicarboylic acid dianhydride, 3,3′,4,4′-benzophenone tetracarboxylic acid dianhydride, 2,2′,3,3′-benzophenone tetracarboxylic acid dianhydride, 4,4′-(p-phenylenedioxy)diphthalic acid dianhydride, 4,4′-(m-phenylenedioxy)diphthalic acid, ethylene tetracarboxylic acid dianhydride, 3-carboxymethyl-1,2,4-cyclopentane tricarboxylic acid dianhydride, 1,1-bis(2,3-dicarboxyphenyl)ethane dianhydride, bis(2,3-dicarboxyphenyl)methane dianhydride, bis(3,4-dicarboxyphenyl)methane dianhydride, or 4,4′-(hexafluoroisopropylidene)diphthalic acid anhydride may be used.

These diamines and dianhydride may be used alone or as a combination of two or more species.

In addition, besides the diamines or dianhydride described above as a raw material of a polyimide or a polyamic acid, as a component which may improve adhesiveness to a device material to an extent not to reduce a refractive index or transparency, a diamine of silicone or a diamine or an anhydride including an alkali or an acid in a side chain may be used. Specifically, as a diamine including a silicone, KF8010, X-22-161 A, or X-22-161 B (ShinEtsu Silicones) and, as a diamine including an alkyl group in a side chain, 4,4′-diamino-3-dodecyldiphenylether or 1-octadecanoxy-2,4-diaminobenzene may be used.

In addition, specific examples of the organic solvent used for the synthesis of a PAA solution include aprotic polar solvents including formamides such as N,N-dimethylformamide and N,N-diethylformamide, acetamides such as N,N-dimethylacetamide and N,N-diethylacetamide, and pyrrolidones such as N-methyl-2-pyrrolidone. These organic solvents may be used independently or by being mixed together.

The two-step synthesis method is classified into heating imidization and chemical imidization according to the imidization method.

Heating imidization is a method of causing imidization by heating PAA in nitrogen atmosphere to 250° C. or a higher temperature. In the heating, the temperature rising condition is an important factor accompanying a change in the physical structure. Heating imidization provides an advantage that imidization may be easily performed simply by heating to 250° C. or a higher temperature. In addition, according to the need, a reaction catalyst such as 3-hydroxypyridine, 4-hydroxypyridine, phthalazine, and bezimidazole may be added to perform heating imidization at a lower temperature. Chemical imidization is a method of causing imidization by using a dehydration cyclization agent (mixture of an acid anhydride and a tertiary amine) such as acetic acid anhydride and pyridine in a temperature range from about room temperature to about 100° C. In an embodiment of the present disclosure, either heating imidization or chemical imidization may be used. According to the purpose, an appropriate method may be chosen to prepare a polyimide.

One-Step Synthesis Method

One-step synthesis method is to synthesize PI which may be dissolved in an amide solvent or a phenol solvent without passing through PAA. For example, a molar equivalent of monomer is dissolved in a solvent such as m-cresol and the resulting mixture is kept at a temperature about 200° C. for a few hours in existence of an alkali solvent such as isoquinoline to synthesize PI.

2.3 Method of Preparing Nanocomposite

By the method described above, a high refractive index inorganic oxide dispersed at a nanometer level and a high refractive index polyamic acid and polyimide may be obtained. By mixing the two components by using an appropriate method, while repressing coagulation, a high refractive index inorganic oxide particle may be filled at a high filling ratio in a polyamic acid and a polyimide solvent having excellent heat resistance to prepare a high refractive index nanocomposite having a refractive index of 1.7 or higher.

In the preparation of a nanocomposite, beside the components described above, an adhesion aid, a surfactant, and a thermal acid generator may be used according to the need.

An example of the method of preparing a nanocomposite using an inorganic oxide nanoparticle and a polyamic acid is described below.

Preparation Method NO. 1 includes following two steps. In the first step, the surface-modified inorganic oxide nanoparticle (12) is obtained by the method described above. Subsequently, in the second step, the surface-modified inorganic oxide nanoparticle (12) obtained in the first step is mixed with a polyamic acid obtained by the two-step synthesis method described above, and the resulting mixture is heat-treated. As a condition of the heat treatment, heating is performed at 250° C. or a higher temperature at which a polyamic acid is imidized as described above. By the heat treatment, a portion of the carboxylic groups included in the polyamic acid is bound to an epoxy group and other carboxylic groups are bound to an amide group included in the polyamic acid to be imidized. In addition, by the interaction between the first functional group (12b) of the surface-modified inorganic oxide nanoparticle (12) and a polyimide backbone of the matrix resin (11), the surface-modified inorganic oxide nanoparticle (12) is uniformly distributed in the matrix resin (11).

As described above, Preparation Method NO. 1 is a method to directly mix the surface-modified inorganic oxide nanoparticle (12) and a polyamic acid to prepare the nanocomposite (10) wherein the surface-modified inorganic oxide nanoparticle (12) is dispersed in matrix resin (11) including a polyimide (This method is hereinafter referred to as “direct mixing method”). However, in the direct mixing method, the surface-modified inorganic oxide nanoparticle (12) is put into a highly viscous polyamic solvent and a drastic viscosity change may occur. Thus, the surface-modified inorganic oxide nanoparticle (12) may be easily coagulated. The formed coagulants may be re-dispersed by radiating ultrasonic wave, but re-dispersion takes a long time.

Therefore, the inventors invented, as Preparation Method NO. 2, a method of performing a polymerization reaction of polyamic acid in a suspension of the surface-modified inorganic oxide nanoparticle (12) to mix the surface-modified inorganic oxide nanoparticle (12) and a polyamic acid (This method is hereinafter referred to as “in situ polymerization method.”) More specifically, in the Preparation Method NO. 2 (“in situ polymerization method”), the surface-modified inorganic oxide nanoparticle (12) is obtained in the same method as the Preparation Method NO. 1. Subsequently, in the Preparation Method NO. 2, the surface-modified inorganic oxide nanoparticle (12) is mixed with a diamine and an acid dianhydride and the diamine and the acid dianhydride are reacted with each other to produce a mixture of the surface-modified inorganic oxide nanoparticle (12) and a polyamic acid. The resulting mixture is heat-treated. The heat treatment is performed by the same method as that of the direct mixing method.

In the in situ polymerization method described above, mixing may be performed by gradually increasing viscosity to repress coagulation of an inorganic oxide particle during the mixing without causing a drastic change in the viscosity. In addition, by using the in situ polymerization method, the time required to prepare a composite with the inorganic oxide particle and a polyimide, including the time for imidization of a polyamic acid, may be greatly reduced.

3. Composition of Surface Light Emitting Device

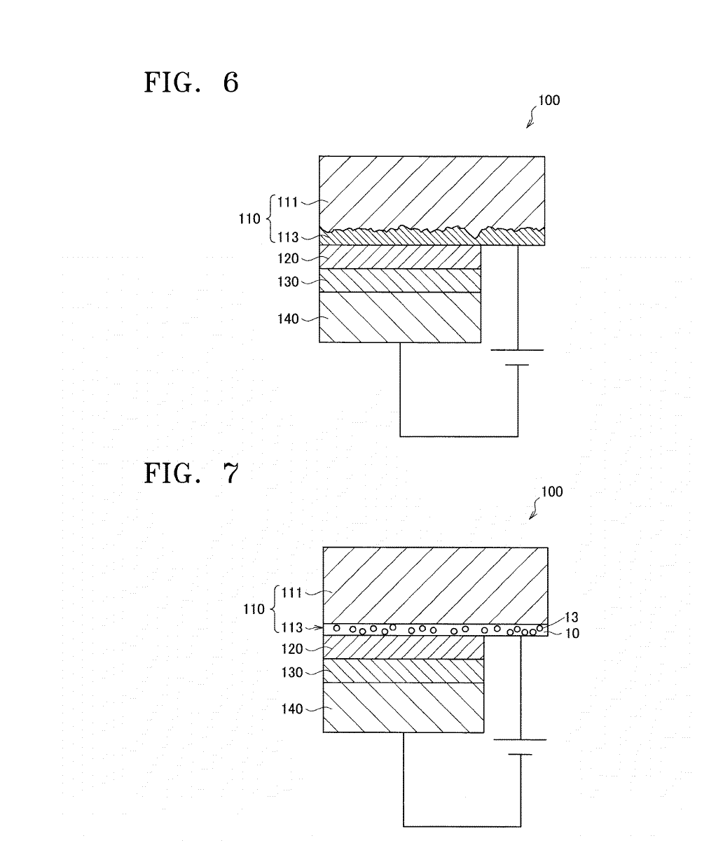

For the next, referring to FIGS. 6 through 8, the composition of a surface light emitting device employing the nanocomposite (10) according to the embodiment of the present disclosure described above is described hereinafter. FIGS. 6 through 8 show the cross sectional view of a surface light emitting device according to the embodiment of the present disclosure.

As shown in FIGS. 6 through 8, the surface light emitting device (100) according to the embodiment of the present disclosure mainly includes a translucent substrate (110), a transparent conductive film (a transparent electrode) (120), an organic electroluminescent layer (130), and a cathode (140).

Generally, in the surface light emitting device (100) such as an organic electroluminescent device, the light emitted from fluorescent body in the organic electroluminescent layer (130) is radiated omnidirectionally and emitted through a hole transfer layer (not shown), the transparent conductive film (120) which is an anode, and the translucent substrate (110) into air. Or, in the opposite direction of the light extraction direction (toward the translucent substrate (110)), the light may be reflected by the cathode (140) and emitted through organic electroluminescent layer (130), the hole transfer layer (not shown), the transparent conductive film (120), and the translucent substrate (110) into air. However, as the light passes through a boundary interface of each medium, when the refractive index of the light incident side medium is greater than that of the light emitting side medium, the light having an incidence angle greater than a critical angle, which is an angle making the light emitting angle of the refracted wave be 90°, does not pass through the boundary interface but totally reflected. Thus, the light is not emitted into air.

The relationship between a refraction angle of light and a refractive index of a medium at the boundary interface between different media generally follows Snell's law. According to Snell's law, when light moves from Medium 1 having a refractive index of n1 to Medium 2 having a refractive index of n2, the relation between the incidence angle θ1 and the refraction angle θ2 is n1 sin θ1=n2 sin θ2. In this relation, when n1>n2, the incidence angle making θ2=90°, which is θ1=Arcsin(n2/n1), is called a critical angle. When the incidence angle is greater than the critical angle, light is totally reflected at the boundary interface between Medium 1 and Medium 2. Therefore, in a surface light emitting device which emits light isotropically, the light having an emitting angle greater than the critical angle repeatedly undergoes total reflection at the boundary interface and is confined in the device and thus it is not emitted into air.

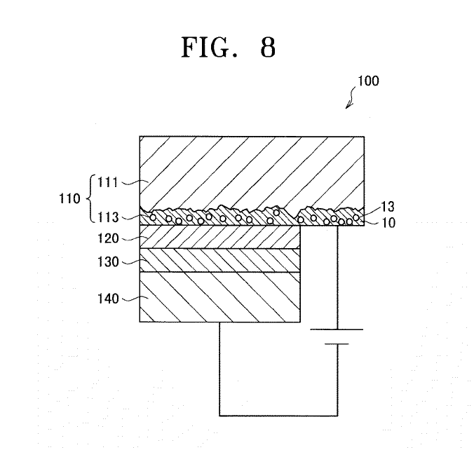

As the light extraction efficiency of a surface light emitting device is low for this reason, in an embodiment of the present disclosure, the light extraction efficiency was improved by preparing the surface light emitting device (100) shown in FIGS. 6 through 8. As shown in FIG. 6, on a transparent substrate (111) having an embossed surface, a covering layer (113) which is formed with the nanocomposite (10) is formed to form the translucent substrate (110). As shown in FIG. 7, a scattering particle (13) is uniformly dispersed in the high refractive index nanocomposite (10) to form the covering layer (113). In addition, the covering layer (113) is formed on a transparent substrate (111) having no embossed surface (that is, having a flat surface). As a result, the translucent substrate (110) is formed. FIG. 8 combines the surface light emitting device (100) of FIG. 6 and the surface light emitting device (100) of FIG. 7. In other words, in the surface light emitting device (100) of FIG. 8, on the transparent substrate (111) having an embossed surface, the covering layer (113) which is formed with the nanocomposite (10) is formed. In addition, the covering layer (113) is formed by uniformly dispersing the scattering particle (13) on the nanocomposite (10). By preparing a means to convert the light emitting angle by the method described above, according to Snell's law, the light which is totally reflected at a boundary interface between layers and thus may not be extracted from the inside of a device may be extracted to the outside of the device (into air). Individual units of the surface light emitting device (100) shown in FIG. 6 are described in detail hereinafter. Except the differences described above, the surface light emitting device (100) of FIG. 7 and that of FIG. 8 have the same units as those of the surface light emitting device (100) of FIG. 6.

Translucent Substrate (110)

The translucent substrate (110) is formed by covering the transparent substrate (111) with the covering layer (113) which is formed with the nanocomposite (10).

The transparent substrate (111) is a substrate formed with a transparent material, for example, glass such as soda lime glass and alkali-free glass or transparent plastic. Transparent plastics to form the translucent substrate (110) include insulating organic materials, and, for example, polyethersulfone (PES), polyacrylate (PAR), polyetherimide (PEI), polyethylene naphthalate (PEN), polyethylene terephthalate (PET), polyphenylene sulfide (PPS), polyarylate, polyimide, polycarbonate (PC), cellulose triacetate (TAC), or cellulose acetate propionate (CAP) may be used.

On one surface of the transparent substrate (111), an embossed surface is prepared. A method of preparing the embossed surface is not particularly limited. For example, sand blasting, thermal patterning, or chemical etching may be used. The embossed surface may have a randomized embossing which causes a confusion to incidence light which is generated at the organic electroluminescent layer (130), passes through the transparent conductive film (120), and enters into the translucent substrate (110), or the embossed surface may have a uniform structural unit such as a lens structure or a pyramidal structure. As an embossing surface is prepared on the surface of the transparent substrate (111) to scatter the light entering into the embossed surfaced, in the light moving perpendicularly to the transparent substrate (111), the ratio of the light which does not change the direction but transmits the transparent substrate (111) is decreased. As the ratio of scattered light (transmitting light which is not perpendicular to the transparent substrate (111)) is increased, the extraction efficiency in the surface light emitting device (100) may be improved.

In addition, a method of forming the covering layer (113) on the transparent substrate (111) is not particularly limited, but, for example, by coating a mixture solution of a surface-modified inorganic oxide nanoparticle and a polyamic acid on the transparent substrate (111), drying the coated mixture solution, and performing imidization by heat treatment, a nanocomposite may be formed on the transparent substrate (111). A coating method is not particularly limited, and a known method such as spin coating, doctor blade method, applicator method, casting method, dipping method, and spraying coating method may be used.

Transparent Conductive Film (120)

The transparent conductive film (120), which is a layer functioning as an anode of the surface light emitting device (100), is formed with a conductive and transparent material to extract light to the outside of the surface light emitting device (100). Specifically, as a material to form the transparent conductive film (120), a transparent oxide semiconductor, particularly indium tin oxide (ITO), IZO (InZnO), ZnO, or In₂O₃, having high work function, may be preferably used.

Organic Electroluminescent Layer (130)

The organic electroluminescent layer (130) includes at least a hole transfer layer and a light emitting layer. In addition, the organic electroluminescent layer (130) may additionally include a hole injection layer. When the organic electroluminescent layer (130) at least one of a hole transfer layer and a hole injection layer, the hole injection layer is arranged to the side closer to the transparent conductive film (120) than the hole transfer layer. In addition, a light emitting layer is arranged to the side farther from the transparent conductive film (120) than the hole transfer layer.

As a hole transfer material for forming the hole transfer layer, a known material, for example, α-naphthylphenylbiphenyl diamine (α-NPD) N,N′-Bis(naphthalen-1-yl)-N,N′-bis(phenyl)-benzidine (NPB), N,N′-bis(3-methylphenyl)-N,N′-bis(phenyl)-benzidine (TPD), tetraacetoporhyrin (TACP), or a triphenyl tetramer may be used. In addition, as a hole injection material forming the hole injection layer, a known material, for example, polyaniline, polypyrrole, copper phthalocyanine, or poly(3,4-ethylenedioxythiophene) poly(styrenesulfonate) (PEDOT:PSS) may be used.

An organic light emitting layer may include one layer or two or more layers among a red light emitting layer, a green light emitting layer, and a blue light emitting layer.

As a material forming a red light emitting layer, for example, tetraphenylnaphthacene (Rubrene), tris(1-phenylisoquinoline)iridium(III) (Ir(piq)₃), bis(2-benzo[b]thiophene-2-yl-pyridine)(acetylacetonate)iridium(III) (Ir(btp)₂(acac)), tris(dibenzoylmethane)phenanthroline europium (III) (Eu(dbm)₃(phen)), tris[4,4′-di-tert-butyl-(2,2′)-bipyridine]ruthenium (III) complex (Ru(dtb-bpy)₃*2(PF₆)), DCM1, DCM2, Eu (thenoyltrifluoroacetone)₃ (Eu(TTA)₃), or butyl-6-(1,1,7,7-tetramethyljulolidyl-9-enyl)-4H-pyran (DCJTB) may be used. In addition, polymer light emitting materials such as polyfluorene-based polymers and polyvinyl-based polymers may be used.

In addition, a material forming a green light emitting layer, for example, Alq₃, 3-(2-benzothiazolyl)-7-(diethylamino)coumarin (Coumarin 6), 2,3,6,7-tetrahydro-1,1,7,7-tetramethyl-1H,5H,11H-10-(2-benzothiazolyl)quinolizino-[9,9a,1gh]coumarin (C545T), N,N′-dimethyl-quinacridone (DMQA), or tris(2-phenylpyridine)iridium (III) (Ir(ppy)₃) may be used. In addition, polymer light emitting materials such as polyfluorene polymers and polyvinyl polymers may be used.

In addition, a material forming a blue light emitting layer, for example, oxadiazole dimer dyes (such as Bis-DAPDXP), spiro compounds (such as Spiro-DPVBi and Spiro-6P), triarylamine compounds, bis(styryl)amine compounds (such as DPVBi and DSA), 4,4′-bis(9-ethyl-3-carbazovinylene)-1,1′-biphenyl (BCzVBi), perylene, 2,5,8,11-tetra-tert-butylperylene (TPBe), 9H-carbazole-3,3′-(1,4-phenylene-di-2,1-ethene-diyl)bis[9-ethyl-(9C)] (BCzVB), 4,4-bis[4-(di-p-tolylamino)styryl]biphenyl (DPAVBi), 4-(di-p-tolylamino)-4′-[(di-p-tolylamino)styryl]stilbene (DPAVB), 4,4′-bis[4-(diphenylamino)styryl]biphenyl (BDAVBi), or bis(3,5-difluoro-2-(2-pyridyl)phenyl-(2-carboxypyridyl)iridium III (FIrPic) may be used. In addition, polymer light emitting materials such as polyfluorene-based polymers and polyvinyl-based polymers may be used.

In addition, the organic electroluminescent layer (130) may include an electron transfer layer or an electron injection layer in order from the side closer to the cathode (140) than to the light emitting layer. As an electron transfer material to form an electron transfer layer, a known material such as oxazole derivatives (such as PBD and OXO-7), triazole derivatives, boron derivatives, silole derivatives, and Alq₃ may be used. In addition, as an electron injection material, a known material, for example, LiF, Li₂O, CaO, CsO, or CsF₂ may be used.

Cathode (140)

As a material to form the cathode (140), a metal, particularly a metal having a small work function, such as Ag, Mg, Al, Pt, Pd, Au, Ni, Nd, Ir, Cr, Li, Ca, or a compound thereof may be used.

4. Method of Preparing Surface Light Emitting Device

The composition of the surface light emitting device (100) according to an embodiment of the present disclosure is above described in detail. Subsequently, a method of preparing the surface light emitting device (100) according to an embodiment of the present disclosure is described in detail. In addition, the description below is about a method of preparing the surface light emitting device (100) shown in FIG. 6. The method of preparing the surface light emitting device (100) shown in FIG. 7 is formed by omitting the treatment to form an embossed surface in the method described below and adding a treatment to disperse a scattering particle in a nanocomposite to the method described below. The method of preparing the surface light emitting device (100) shown in FIG. 8 is formed by adding a treatment to disperse a scattering particle in a nanocomposite to the method described below. The detailed preparation method is described in Examples.

First, on the surface of the transparent substrate (111) of soda lime glass or alkali-free glass, an embossed surface is formed by a method such as sand blasting and, on the formed embossed surface, a doctor blade is used to coat a mixture solution of a surface-modified inorganic oxide nanoparticle and a polyamic acid. Next, the transparent substrate (111) coated with the mixture solution is transferred to a hot air drying equipment to eliminate the solvent. The transparent substrate (111) from which the solvent has been eliminated is transferred to a furnace and heated to a temperature 250° C. or higher to cause imidization. As a result, as the covering layer (113), which is formed with a nanocomposite in which a surface-modified inorganic oxide nanoparticle is dispersed in a polyimide, is formed on the surface of the transparent substrate (111), the translucent substrate (110) is formed.

Next, on the translucent substrate (110), a film of ITO, IZO (InZnO), ZnO, or In₂O₃ is formed by a method such as sputtering to form the transparent conductive film (transparent electrode) (120). In addition, by depositing a hole transfer material or a light emitting material on the transparent conductive film (120), the organic electroluminescent layer (130) is formed. Then, on the organic electroluminescent layer (130), a metal such as Ag, Mg, or Al is deposited to form the cathode (140) so that the transparent substrate (111) employing the organic electroluminescent layer (130) may be prepared. In addition, as a method of forming the organic electroluminescent layer (130) or the cathode (140), a known method such as vacuum evaporation, casting method (spin casting, dipping, etc.), inkjet method, and printing (type printing, gravure printing, offset printing, screen printing, etc.) may be used.

As the surface light emitting device (100) prepared by the method described above includes a high refractive index nanocomposite having a high transparency formed on the translucent substrate (110) which may improve the light emitting efficiency of a surface light emitting device, the surface light emitting device (100) may be preferably used for a display device or a lighting instrument.

### EXAMPLES

Hereinafter, the embodiments of the present disclosure are described in detail with reference to Examples, but the embodiments of the present disclosure are not limited thereto.

### Synthesis Example 1

First, as an example of surface-modified inorganic oxide nanoparticle, a method of synthesizing titanium oxide of which surface is modified with the first functional group and the second functional group is described. In Examples, a solid content concentration refers to the wt % of the solid content to the total weight of the solid content and the liquid content.

Into a reaction vessel fitted with a cooler, a thermometer, and a nitrogen inlet tube, 50 g of a methanol solution of a rutile-type titanium oxide (Sakai Chemical Industry Co., Ltd.) (solid content concentration 15 wt %) of which surface is not modified was put. Then, 2.8 g of aminopropyltrimethoxysilane (APTES) was added and 50 g of N-methylpyrrolidone (NMP) were further added. Subsequently, the lid of the reaction vessel was closed and the mixture solution was stirred at 60° C. for three hours to obtain a solution of titanium oxide of which surface is modified with an amino group.

The solution was cooled to room temperature and the solid content was separated by centrifugation. Then, 62.5 ml of NMP was added to the solid content which was scrubbed with an ultrasonic cleaner. The process using the centrifugation and the ultrasonic cleaner was repeated for two times to obtain an NMP slurry of TiO₂ of surface is modified with an amino group (TiO₂-APTES). The mean particle diameter of the obtained particle was 7 nm by direct observation method and 110 nm by dynamic scattering method.

Next, to the slurry, 2.12 g of phthalic acid anhydride (Wako Pure Chemical Industry Co., Ltd.) and 0.85 g of pyridine is added and the resulting mixture was stirred in nitrogen atmosphere for 15 hours to imidize the amino group. After stirring, the solid content was again separated by centrifugation and NMP was added to the solid content to make the solid content concentration be 25 wt %. Then, the solid content was scrubbed with an ultrasonic cleaner to obtain an NMP slurry of TiO₂ of surface is modified with the first functional group (TiO₂-Imd).

The mean particle diameter of the obtained particle was 7 nm by direct observation method and 80 nm by dynamic scattering method. Next, 3-glycidoxypropyltriethoxysilane is added to the TiO₂-Imd slurry obtained by the method described above. After closing the lid of the reaction vessel, the resulting mixture solution was stirred at 60° C. for three hours. As a result, an NMP slurry including 25 wt % of titanium oxide particle (TiO₂-ImdG) (solid content) of which surface is modified with the first functional group and the second functional group was obtained. In addition, by FT-IR, modification of the surface of the titanium oxide particle with the first functional group and the second functional group was verified. The mean particle diameter of the obtained particle was 7 nm by direct observation method and 82 nm by dynamic scattering method. The measurement by dynamic scattering method was performed by using DLS instrument (Otsuka Electronics Co., Ltd).

### Synthesis Example 2

Except using o-phosphorylethanolamine as a surface covering agent instead of aminopropyltrimethoxysilane in Synthesis Example 1, the same treatment as that of Synthesis Example 1 was performed. As a result, an NMP slurry of titanium oxide (TiO₂-NPEPIG) of which surface is modified with the first functional group and the second functional group was obtained. By FT-IR, modification of the surface of the titanium oxide particle with the first functional group and the second functional group was verified. The mean particle diameter of the obtained particle was 8 nm by direct observation method and 75 nm by dynamic scattering method.

### Synthesis Example 3

Except using 2-(3,4-epoxycyclohexyl)ethyltrimethoxysilane as a surface covering agent instead of 3-glycidyltriethoxysilane in Synthesis Example 1, the same treatment as that of Synthesis Example 1 was performed. As a result, an NMP slurry of titanium oxide (TiO₂-ImdE) of which surface is modified with the first functional group and the second functional group was obtained. By FT-IR, modification of the surface of the titanium oxide particle with the first functional group and the second functional group was verified. The mean particle diameter of the obtained particle was 8 nm by direct observation method and 76 nm by dynamic scattering method. Synthesis Examples 1 through 3 are examples of the surface modification method NO. 1.

### Synthesis Example 4

Into a reaction vessel fitted with a cooler, a thermometer, and a nitrogen inlet tube, 57.84 g of NMP was put. In addition, 7.05 g of o-phosphorylethanolamine was added and dissolved in NMP. 7.41 g of phthalic acid anhydride was added to a solution in which o-phosphorylethanolamine was dissolved and the o-phosphorylethanolamine and the phthalic acid anhydride were reacted in nitrogen atmosphere at room temperature for 15 hours. 5.1 g of acetic acid anhydride and 4.0 g of pyridine were added to the obtained solution and the o-phosphorylethanolamine and the phthalic acid anhydride were reacted at 90° C. for two hours.

Next, excess acetic acid and pyridine were eliminated by using an evaporator to obtain a solution of a phosphate ester having an imide backbone. To 14.56 g of the obtained phosphate ester solution, 50 g of a methanol solution of a rutile-type titanium oxide (Sakai Chemical Industry Co., Ltd.) (solid content concentration 15 wt %) of which surface is not modified and 50 g of N-methylpyrrolidone were put in. Then, the lid of the reaction vessel was closed and the resulting mixture was stirred at 60° C. for three hours. As a result, a solution of titanium oxide of which surface is modified with the first functional group was obtained.

Subsequently, the solution was cooled to room temperature and the solid content was separated from the solution by centrifugation. Then, 62.5 ml of NMP was added to the solid content which was scrubbed with an ultrasonic cleaner. To the TiO₂-Imd slurry obtained by the method described above, 3 g of 3-glycidyltrimethoxysilane was added. The lid of the reaction vessel was closed and the mixture solution was stirred at 60° C. for three hours. As a result, an NMP slurry including 25 wt % of a titanium oxide particle (TiO₂-NPEPIG(2)) (solid content) of which surface is modified with the first functional group and the second functional group was obtained. The mean particle diameter of the obtained particle was 7 nm by direct observation method and 83 nm by dynamic scattering method.

### Synthesis Example 5

Except using 50 g of an MEK solution of zirconium oxide (Sakai Chemical Industry Co., Ltd.) (solid content concentration 30 wt %), to make the weight of APTES be 7.99 g, instead of a methanol solution of a rutile-type titanium oxide in Synthesis Example 1, the same treatment as that of Synthesis Example 1 was performed. As a result, an NMP slurry including 25 wt % of a zirconium oxide particle (ZrO2-ImdG) (solid content) of which surface is modified with the first functional group and the second functional group was obtained. By FT-IR, modification of the surface of the zirconium oxide particle with the first functional group and the second functional group was verified. The mean particle diameter of the obtained particle was 3 nm by direct observation method and 36 nm by dynamic scattering method. Synthesis Examples 4 through 5 are examples of the surface modification method NO. 2.

### Synthesis Example 6

Solid content was separated by centrifugation from 50 g of a methanol solution of a titanium oxide (Sakai Chemical Industry Co., Ltd.) (solid content concentration 15 wt %) and then 50 ml of NMP was added to the solid content. Next, the solid content was scrubbed with an ultrasonic cleaner to obtain an NMP slurry including 15 wt % of a titanium oxide particle. The mean particle diameter of the obtained particle was 7 nm by direct observation method and 130 nm by dynamic scattering method. This indicated that the surface of the titanium oxide particle in Synthesis Example 6 was not modified.

The particles synthesized in the above Synthesis Examples and the diameter of the particles are listed in Table 1.

TABLE 1

| | | Particle | |
|---|---|---|---|
| | | diameter (nm) | Particle |
| | | by direct | diameter (nm) |
| | | observation | by dynamic |
| | Name | method | light scattering |
| Synthesis | TiO₂-APTES | 7 | 110 |
| Example 1-1 | | | |
| Synthesis | TiO₂-Imd | 7 | 80 |
| Example 1-2 | | | |
| Synthesis | TiO₂-ImdG | 7 | 82 |
| Example 1-3 | | | |
| Synthesis | TiO₂-NPEPIG | 8 | 75 |
| Example 2 | | | |
| Synthesis | TiO₂-ImdE | 8 | 76 |
| Example 3 | | | |
| Synthesis | TiO₂-NPEPIG(2) | 7 | 83 |
| Example 4 | | | |
| Synthesis | ZrO₂-ImdG | 3 | 36 |
| Example 5 | | | |
| Synthesis | TiO₂ | 7 | 130 |
| Example 6 | | | |

### Synthesis Example 7

A polyamic acid was synthesized by the following method. Into a reaction vessel employing a nitrogen inlet tube, 7.08 g of bis(3-aminophenyl)sulfone and 65.12 g of NMP were added to completely dissolve 7.08 g of bis(3-aminophenyl)sulfone in NMP at room temperature. Next, 9.02 g of 4-(2,5-dioxotetrahydrofuran-3-yl)-tetraene-1,2-dicarboxylic acid anhydride was added to the solution and the resulting solution was stirred at room temperature in nitrogen atmosphere for 15 hours. As a result, an NMP solution (PAA-1) including 20 wt % of 20% polyamic acid (solid content) was obtained.

### Example 1

Next, a preparation example of the nanocomposite (10) is described as an Example. 4.20 g of the NMP slurry of TiO₂-ImdG (solid content 25 wt %) synthesized in Synthesis Example 1, 4.90 g of the NMP solution of PAA-1 synthesized in Synthesis Example 7 (solid content 20 wt %), and 1.05 g of NMP were mulled with a rotation-revolution mixer (Awatori Rentaro, Shinki) for five minutes. Then, ultrasonic wave was radiated to the mulled solution. The resulting mixture solution was coated on a glass substrate by spin coating.

Then, the glass substrate on which the mixture solution was coated was treated on a hot plate at 100° C. for one hour. The treated glass substrate was put into an oven to which nitrogen might be injected. The glass substrate was heated in nitrogen atmosphere stepwise as 100° C. for 30 min, 150° C. for 30 min, and 250° C. for 1 hour to obtain a nanocomposite of which TiO₂-ImdG particle filling ratio was 30 vol %.

The thickness of the film of the obtained nanocomposite measured with a stylus type thickness gauge (DEKTAK, ULVAC) was 1.3 μm. The refractive index of the film was 1.78, the haze value was 1.2%, and the total light transmittance was 89%. The refractive index was measured with a prism coupler (Model 2010, Metricon) and a UVISEL spectroscopic ellipsometer (HORIBA•Jobin Yvon). The total light transmittance and the haze value were measured by using the Hazemeter Haze Guide II (Toyo Electric). The rest is the same as above.

In addition, the mixture solution was coated on a glass substrate by using a bar coater (No. 14, Tester Industry). The glass substrate coated with the mixture solution was put onto a hot plate and treated at 100° C. for one hour. The treated glass substrate was put into an oven to which nitrogen might be injected. The glass substrate was heated in nitrogen atmosphere stepwise as 100° C. for 30 min, 150° C. for 30 min, and 250° C. for 1 hour to obtain a nanocomposite of which TiO₂-ImdG particle filling ratio was 30 vol %. The thickness of the obtained film was 6.52 μm and no crack was observed when the film was observed with a microscope.

### Examples 2 Through 8

A nanocomposite was prepared by varying the type of oxide nanoparticle and the ratio of the oxide nanoparticle to a polyamic acid. The details are shown in Table 2. Examples 1 through 8 are examples of Preparation Method NO. 1.

### Example 9

Into a reaction vessel employing a nitrogen inlet tube, 4.20 g of the NMP slurry of TiO₂-ImdG (solid content 25 wt %) synthesized in Synthesis Example 1 and 4.97 g of NMP were put. Next, while stirring the NMP slurry, 0.43 g of bis(3-aminophenyl)sulfone was added in the NMP slurry and the bis(3-aminophenyl)sulfone was completely dissolved at room temperature. Then, 0.54 g of 4-(2,5-dioxotetrahydrofuran-3-yl)-tetraene-1,2-dicarboxylic acid anhydride was added to the mixture solution and the resulting mixture solution was in situ stirred at room temperature in nitrogen atmosphere for 15 hours to obtain a mixture solution of a polyamic acid and TiO₂-ImdG.

Afterwards, the mixture solution was treated by a treatment the same as that of Example 1 to obtain two nanocomposites of which TiO₂-ImdG particle filling ratio was 30 vol %. The thickness of the films of the obtained nanocomposites measured with a stylus type thickness gauge (DEKTAK, ULVAC) was 1.3 μm and 6.21 μm. The refractive index of the film of 1.3 μm thickness was 1.92, the haze value was 1.4%, and the total light transmittance was 88%. No crack was observed on the film of 6.21 μm thickness when the film was observed with a microscope.

### Examples 10 and 11

Except changing the mixing ratio of TiO₂-ImdG, bis(3-aminophenyl)sulfone, and 4-(2,5-dioxotetrahydrofuran-3-yl)-tetraene-1,2-dicarboxylic acid anhydride, which is the mixing ratio of TiO₂-ImdG and a polyamic acid, the same treatment as that of Example 9 was performed. The details are shown in Table 2. Examples 9 through 11 are examples of Preparation Method NO. 2.

### Comparative Example 1

A comparative example of a nanocomposite is described hereinafter. 4.2 g of the NMP slurry of the intermediate particle (TiO₂-APTES) (solid content 25 wt %) synthesized in Synthesis Example 1, 4.9 g of the NMP solution of PAA-1 synthesized in Synthesis Example 7 (solid content 20 wt %), and 1.05 g of NMP were mulled with a rotation-revolution mixer (Awatori Rentaro, Shinki) for five minutes. Then, ultrasonic wave was radiated for 3 hours to the mulled solution to prepare a mixture solution.

The obtained mixture solution was coated on a glass substrate by spin coating. Then, the glass substrate was treated on a hot plate at 100° C. for one hour.

The treated glass substrate was put into an oven to which nitrogen might be injected. The glass substrate was heated in nitrogen atmosphere stepwise as 100° C. for 30 min, 150° C. for 30 min, and 250° C. for 1 hour to obtain a nanocomposite of which TiO₂-APTES particle filling ratio was 30 vol %. The thickness of the film of the obtained nanocomposite measured with a stylus type thickness gauge (DEKTAK, ULVAC) was 1.2 μm. The refractive index of the film was 1.79, the haze value was 12.8%, and the total light transmittance was 72%.

In addition, the mixture solution was coated on a glass substrate by using a bar coater (No. 14, Tester Industry). The glass substrate coated with the mixture solution was put onto a hot plate and treated at 100° C. for one hour. The treated glass substrate was put into an oven to which nitrogen might be injected. The glass substrate was heated in nitrogen atmosphere stepwise as 100° C. for 30 min, 150° C. for 30 min, and 250° C. for 1 hour to obtain a nanocomposite of which TiO₂-Imd particle filling ratio was 30 vol %. The thickness of the film of the obtained nanocomposite was 6.21 μm and no crack was observed when the film was observed with a microscope.

### Comparative Example 2

4.2 g of the NMP slurry of the intermediate particle (TiO₂-Imd) (solid content 25 wt %) synthesized in Synthesis Example 1 and 4.9 g of the NMP solution of PAA-1 synthesized in Synthesis Example 7 (solid content 20 wt %) were mulled with a rotation-revolution mixer (Awatori Rentaro, Shinki) for five minutes. Then, ultrasonic wave was radiated for 3 hours to the mulled solution to prepare a mixture solution.

The obtained mixture solution was coated on a glass substrate by spin coating. Then, the glass substrate was treated on a hot plate at 100° C. for one hour. The treated glass substrate was put into an oven to which nitrogen might be injected. The glass substrate was heated in nitrogen atmosphere stepwise as 100° C. for 30 min, 150° C. for 30 min, and 250° C. for 1 hour to obtain a nanocomposite of which TiO₂-Imd particle filling ratio was 30 vol %.

The thickness of the film of the obtained nanocomposite measured with a stylus type thickness gauge (DEKTAK, ULVAC) was 1.0 μm. The refractive index of the nanocomposite was 1.83, the haze value was 1.2%, and the total light transmittance was 88%.

In addition, the mixture solution was coated on a glass substrate by using a bar coater (No. 14, Tester Industry). The glass substrate coated with the mixture solution was put onto a hot plate and treated at 100° C. for one hour. The treated glass substrate was put into an oven to which nitrogen might be injected. The glass substrate was heated in nitrogen atmosphere stepwise as 100° C. for 30 min, 150° C. for 30 min, and 250° C. for 1 hour to obtain a nanocomposite of which TiO₂-Imd particle filling ratio was 30 vol %. The thickness of the film of the obtained nanocomposite was 5.73 μm and a number of tiny cracks were observed when the film was observed with a microscope.

### Comparative Example 3

Except changing the quantity of TiO₂-Imd, the same treatment as that of Comparative Example 2 was performed. The details are shown in Table 2.

### Comparative Example 4

Except using the NMP slurry of the TiO₂ prepared in Synthesis Example 6 instead of the NMP slurry of the intermediate particle (TiO₂-APTES) in Comparative Example 1, the same treatment as that of Comparative Example 1 was performed. The details of Comparative Examples 1 through 4 are shown in Table 2.

TABLE 2

| Composition | Ex. 1 | Ex. 2 | Ex. 3 | Ex. 4 | Ex. 5 | Ex. 6 | Ex. 7 | Ex. 8 |
|---|---|---|---|---|---|---|---|---|
| Preparation Method | Direct Mixing Method | | | | | | | |
| TiO₂-ImdG | 10.34 | 13.43 | 15.79 | | | | | |
| TiO₂-NPEPIG | | | | 15.79 | | | | |
| TiO₂-ImdE | | | | | 15.79 | | | |
| TiO₂- | | | | | | 15.79 | | |
| NPEPIG(2) | | | | | | | | |
| ZrO₂-ImdE | | | | | | | 12.95 | 17.31 |
| TiO₂-APTES | | | | | | | | |
| TiO₂-Imd | | | | | | | | |
| TiO₂ | | | | | | | | |
| PAA-1 | 9.66 | 6.57 | 4.21 | 4.21 | 4.21 | 4.21 | 7.05 | 2.69 |
| NMP | 80.00 | 80.00 | 80.00 | 80.00 | 80.00 | 80.00 | 80.00 | 80.00 |
| Total | 100.00 | 100.00 | 100.00 | 100.00 | 100.00 | 100.00 | 100.00 | 100.00 |
| Particle | 30 | 45 | 60 | 60 | 60 | 60 | 30 | 60 |
| Filling Ratio | | | | | | | | |
| (vol %) | | | | | | | | |
| Total Light | 89 | 87 | 83 | 82 | 84 | 83 | 90 | 85 |
| transmittance | | | | | | | | |
| Haze value | 1.2 | 1.4 | 1.1 | 1.5 | 1.2 | 1.4 | 1.1 | 1.5 |
| Refractive | 1.79 | 1.85 | 1.90 | 1.88 | 1.91 | 1.88 | 1.73 | 1.85 |
| Index | | | | | | | | |
| Crack on 5 μm | OK | OK | OK | OK | OK | OK | OK | OK |
| film | | | | | | | | |

| | | | | Comp. | Comp. | Comp. | Comp. |
|---|---|---|---|---|---|---|---|
| Composition | Ex. 9 | Ex. 10 | Ex. 11 | Ex. 1 | Ex. 2 | Ex. 3 | Ex. 4 |
| Preparation Method | in situ polymerization Method | | | | | | |
| TiO₂-ImdG | 11.54 | 16.67 | 13.44 | | | | |
| TiO₂-NPEPIG | | | | | | | |
| TiO₂-ImdE | | | | | | | |
| TiO₂- | | | | | | | |
| NPEPIG(2) | | | | | | | |
| ZrO₂-ImdE | | | | | | | |
| TiO₂-APTES | | | | 11.54 | | | |
| TiO₂-Imd | | | | | 11.54 | 16.67 | |
| TiO₂ | | | | | | | 11.54 |
| PAA-1 | 9.52 | 6.57 | 5.60 | 10.77 | 10.77 | 6.67 | 10.77 |
| NMP | 80.00 | 80.00 | 80.00 | 80.00 | 80.00 | 80.00 | 80.00 |
| Total | 101.06 | 103.24 | 98.71 | 102.31 | 102.31 | 103.34 | 102.31 |
| Particle | 30 | 45 | 60 | 30 | 30 | 60 | 30 |
| Filling Ratio | | | | | | | |
| (vol %) | | | | | | | |
| Total Light | 88 | 87 | 84 | 72 | 88 | 85 | 70 |
| transmittance | | | | | | | |
| Haze value | 1.1 | 1.5 | 1.5 | 12.6 | 1.2 | 1.3 | 14.8 |
| Refractive | 1.79 | 1.85 | 1.90 | 1.78 | 1.83 | 1.86 | 1.80 |
| Index | | | | | | | |
| Crack on 5 μm | OK | OK | OK | OK | NG | NG | NG |
| film | | | | | | | |

“OK” - No cracks in the film
“NG” - cracks occured in the film

Crack Test

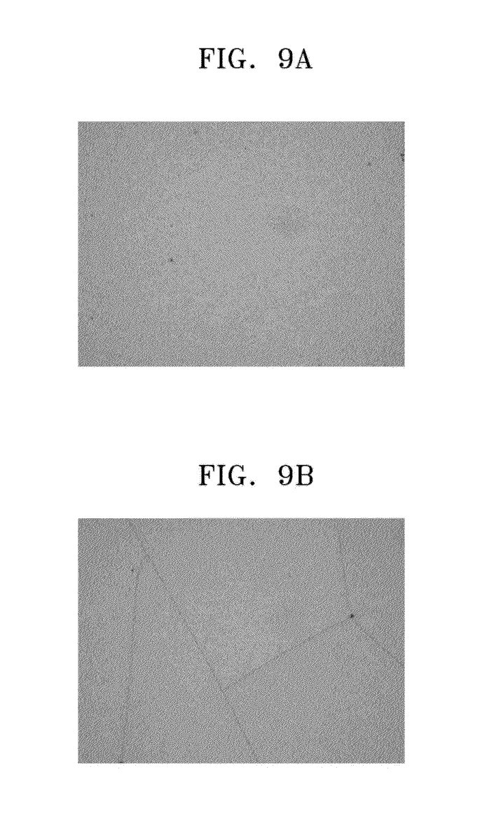

On the nanocomposite films having a thickness of 5 μm or higher, which were formed in Example 1 and Comparative Example 4, generation of a crack was verified. FIG. 9a shows an optical microscopic image of the nanocomposite film of Example 1 and FIG. 9b shows an optical microscopic image of the nanocomposite film of Comparative Example 4. No crack is observed in the image of FIG. 9a, but cracks are shown in the image of FIG. 9b.

Refractive Indices Test

By varying the ratio of the oxide nanoparticle modified with the imide functional group and the epoxy functional group used in Example 1 to a polyamic acid, 1.3 μm thick nanocomposite films having an oxide nanoparticle filling ratio of 0, 15, 30, 40, 45, and 60 vol % were prepared. The nanocomposite films of which filling ratio is 30, 45, and 60 vol % are corresponding to the nanocomposite films of Examples 1, 2, and 3, respectively.

In addition, by varying the ratio of the oxide nanoparticle modified with the imide functional group used in Comparative Example 2 to a polyamic acid, 1.3 μm thick nanocomposite films having an oxide nanoparticle filling ratio of 0, 15, 30, 40, 45, and 60 vol % were prepared. The nanocomposite films of which filling ratio is 30 and 60 vol % are corresponding to the nanocomposite films of Comparative Examples 2 and 3, respectively.

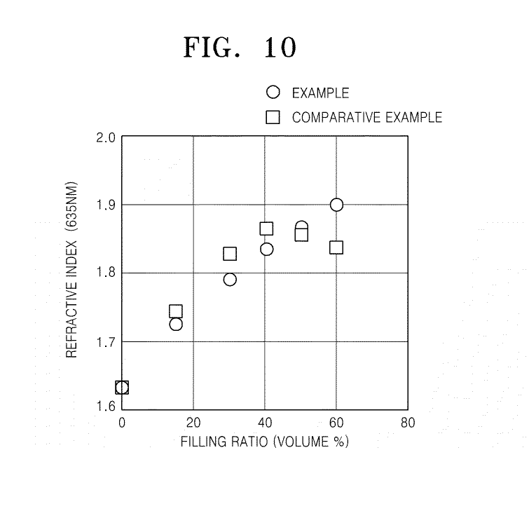

FIG. 10 shows a graph of the measured refractive index of the nanocomposite films depending on the filling ratio of the oxide nanoparticle. As shown in the graph of FIG. 10, with respect to the nanocomposite films according to Examples in which oxide nanoparticles modified with an imide functional group and an epoxy functional group were used, the refractive index was linearly increased to 1.9 depending on the particle filling ratio. However, with respect to the nanocomposite films according to Comparative Examples in which oxide nanoparticles modified only with an imide functional group were used, the refractive index was saturated at 40 vol % of particle filling ratio and not increased further.

### SIGNIFICANCE OF EXAMPLES AND COMPARATIVE EXAMPLES

All the nanocomposites of Examples satisfy the conditions (A) through (D) described above. The reason is presumed that, in Examples, an inorganic oxide nanoparticle having a high refractive index is uniformly dispersed by an interaction between the first functional group and the polyimide part of the matrix resin and tightly bound to the matrix resin by the second functional group.

In other words, in Examples, as a great quantity (30 vol % or higher) of the inorganic oxide particle is uniformly dispersed, the refractive index and the transparency are high. In addition, as the inorganic oxide particle is tightly bound to the matrix resin, even though a great quantity of the inorganic oxide particle is included in the nanocomposite, stripping of the inorganic oxide particle off from the matrix resin is repressed.

On the other hand, Comparative Examples do not satisfy one of the conditions (A) through (D). In other words, it is presumed that, in Comparative Examples, as the inorganic oxide particle does not have the first functional group, the dispersity is lower than that of the particles of Examples and thus the refractive index and the transparency are lower than those of the particles of Examples. It is also presumed that, as the inorganic oxide particle of Comparative Examples does not have the second functional group, the inorganic oxide particle is stripped off from the matrix resin during film thickening of the nanocomposite.

Example in Organic Electroluminescent Device

Using the nanocomposite of Examples, a translucent substrate and an organic electroluminescent device were prepared.

Preparation of Embossed Surface

#800 of alumina powder was sprayed under 0.5 kPa condition on a 0.7 mm thick 50 mm for 50 mm soda lime glass to obtain an embossed substrate. Observation of the embossed substrate with a laser microscope (VK9510, Keyence) showed an embossed surface having surface roughness of Ra=0.7 μm. The total light transmittance and the haze value measured by using the Hazemeter Haze Guide II (Toyo Electric) were 82% and 91%, respectively, indicating that a light scattering layer is formed.

The mixture solution prepared in Example 2 (the mixture solution coated on a glass substrate) was coated on a substrate having an embossed surface and a substrate having no embossed surface (a soda lime glass substrate which has not undergone sand blast processing) by using a doctor blade. Each of the substrates was put onto a hot plated and heated at 100° C. for one hour. Each of the heat-treated substrates was put into an oven to which nitrogen might be injected. Each of the substrates was heated in nitrogen atmosphere stepwise as 100° C. for 30 min, 150° C. for 30 min, and 250° C. for 1 hour to form a nanocomposite layer on each substrate.

The thickness of the nanocomposite film formed on the substrate without an embossed surface, which was measured with a stylus type thickness gauge (DEKTAK, ULVAC), was 10.3 μm. The surface roughness (Ra) of the nanocomposite film was 30 nm or less, indicating that a flat glass layer was formed. The total light transmittance of the nanocomposite film formed on the substrate without an embossed surface was 85% and the haze value was 6%.

On the other hand, the total light transmittance of the nanocomposite film formed on the substrate with an embossed surface was 75%, the haze value was 90%, and the surface roughness (Ra) was 30 nm or less. By the method described above, a flat surface translucent substrate having a light scattering layer therein was prepared.

Mulling of Scattering Particle

4.2 g of the NMP slurry of the TiO₂-ImdG (solid content 25 wt %) synthesized in Synthesis Example 1, 4.9 g of the NMP solution of PAA-1 synthesized in Synthesis Example 7 (solid content 20 wt %), and 0.25 g of SiO₂ particles having a mean particle diameter of 1 μm (Admatechs, Admafine SO-E3) were put into a rotation-revolution mixer (Awatori Rentaro, Shinki). The mixed solution was mulled for 15 minutes and then radiated with ultrasonic wave for three hours to prepare a nanocomposite mixture solution including a scattering particle.

The prepared nanocomposite mixture solution including a scattering particle was coated on a substrate having no embossed surface (a soda lime glass substrate which has not undergone sand blast processing) by using a doctor blade. The substrate coated with the solution was put onto a hot plated and heated at 100° C. for one hour. The heat-treated substrate was put into an oven to which nitrogen might be injected and then heated in nitrogen atmosphere stepwise as 100° C. for 30 min, 150° C. for 30 min, and 250° C. for 30 min to form on the substrate a nanocomposite layer including a scattering particle. The thickness of the nanocomposite film formed on the substrate without an embossed surface, which was measured with a stylus type thickness gauge (DEKTAK, ULVAC), was 9.8 μm. The total light transmittance of the nanocomposite film formed on the substrate without an embossed surface was 65% and the haze value was 83%.

Formation of Embossed Surface and Mulling of Scattering Particle

#800 of alumina powder was sprayed under 0.5 kPa condition on a 0.7 mm thick 50 for 50 soda lime glass to obtain an embossed substrate. In addition, 4.2 g of the NMP slurry of the TiO₂-ImdG (solid content 25 wt %) synthesized in Synthesis Example 1, 4.9 g of the NMP solution of PAA-1 synthesized in Synthesis Example 4 (solid content 20 wt %), and 0.25 g of SiO₂ particles having a mean particle diameter of 1 μm (Admatechs, Admafine SO-E3) were put into a rotation-revolution mixer (Awatori Rentaro, Shinki). The mixed solution was mulled for 15 minutes and then radiated with ultrasonic wave for three hours to prepare a nanocomposite mixture solution including a scattering particle.

The prepared nanocomposite mixture solution including a scattering particle was coated on a substrate having an embossed surface (a soda lime glass substrate which has not undergone sand blast processing) by using a doctor blade. The substrate coated with the solution was put onto a hot plated and heated at 100° C. for one hour. The heat-treated substrate was put into an oven to which nitrogen might be injected and then heated in nitrogen atmosphere stepwise as 100° C. for 30 min, 150° C. for 30 min, and 250° C. for 1 hour to form on the embossed surface substrate a nanocomposite layer including a scattering particle. The total light transmittance of the substrate was 62%, the haze value was 93%, and the surface roughness of the nanocomposite film was 30 nm or less.

The substrate formed by forming a nanocomposite film on a substrate with an embossed surface was named as Substrate A′, the substrate formed by forming on a substrate without an embossed surface a nanocomposite film which was prepared by mulling a scattering particle was named as Substrate B′, the substrate formed by forming on a substrate with an embossed surface a nanocomposite film which was prepared by mulling a scattering particle was named as Substrate C′, the substrate formed by forming a nanocomposite film on a substrate without an embossed surface was named as Substrate D′, and the substrate formed only with soda lime glass was named as Substrate E′.

Afterward, a DC magnetron sputtering instrument was used to prepare a 120 nm of indium zinc oxide (IZO) film on Substrates A′ through E′. Substrates after forming IZO film were named Substrate A to E. Substrates A, B, and C are corresponding to Examples, while Substrates D and E are corresponding to Comparative Examples.

Next, the Substrates A through E on which an IZO film was attached were washed with isopropyl alcohol (IPA) and deionized water and then treated with a UV ozone cleaner. 60 nm of HIL-1 as a hole injection layer, 20 nm of NPD as a hole transfer layer, and 60 nm of Alq₃ as a green light emitting layer were respectively formed by vacuum evaporation.

In addition, 3 nm of LiF as an electron injection layer and 200 nm of Al as a cathode were vacuum deposited to prepare an organic electroluminescent device (surface light emitting device). The organic electroluminescent device prepared by the method described above was not exposed to the surrounding atmosphere but put into a globe box in dry nitrogen atmosphere. The organic electroluminescent device was attached to an encapsulation plate having an absorbent material including barium oxide power by using a UV curing-sealing agent and the sealing agent was cured by UV radiation to encapsulate the organic electroluminescent device.

A measurement instrument built by combing the Source Meter 2400 (KEITHLEY) and the BM-8 luminance meter (TOPCON) was used to measure the current-voltage-luminance property of each device. Almost the same current-voltage property was obtained in all the devices. The measurement at 20 mA/cm² showed that the luminance (electric power efficiency) of Examples (a device employing a nanocomposite and including a scattering factor (embossed surface or scattering particle)) was greater by from about 1.3 times to about 1.6 times than that of Comparative Examples. Table 3 shows the evaluation results.

TABLE 3

| | | | Electric power |
|---|---|---|---|
| | | | efficiency lm/W@ |
| | Substrate | Components | 100 mW/cm² |
| Example | A | embossed substrate/transparent | 2.56 |
| | | nanocomposite layer/IZO/organic EL layer | |
| Example | B | flat substrate/nanocomposite layer including | 2.25 |
| | | scattering particle/IZO/organic EL layer | |
| Example | C | embossed substrate/nanocomposite layer | 2.49 |
| | | including scattering particle/IZO/organic EL | |
| | | layer | |
| Comparative | D | flat substrate/transparent nanocomposite | 1.57 |
| Example | | layer/IZO/organic EL layer | |
| Comparative | E | flat substrate/IZO/organic EL layer | 1.61 |
| Example | | | |

As described above, the nanocomposite (10) according to an embodiment of the present disclosure has excellent heat resistance as it has a matrix resin (11) including a polyimide. In addition, as the surface of the inorganic oxide nanoparticle (12a) is modified with the first functional group (12b) having an imide backbone, the inorganic oxide nanoparticle (12a) is uniformly dispersed in the matrix resin (11). Therefore, the transparency of the nanocomposite (10) is improved. In addition, as the surface of the inorganic oxide nanoparticle (12a) is modified with second functional group (12c) which is tightly bound to the matrix resin (11), the inorganic oxide nanoparticle (12a) is tightly bound to the matrix resin (11). Therefore, crack generation during film thickening is repressed. In other words, even though a great quantity of the inorganic oxide nanoparticle (12a) is included in the nanocomposite (10) is included, crack generation and transparency decrease are repressed. Thus, a great quantity of the inorganic oxide nanoparticle (12a) may be included in the nanocomposite (10) and the refractive index of the nanocomposite (10) is further increased.

In addition, in an embodiment of the present disclosure, as second functional group (12c) has an epoxy group, it may be tightly bound to the matrix resin (11).

In addition, as the nanocomposite (10) includes the inorganic oxide nanoparticle (12a) of from about 30 to about 60 vol %, the refractive index of the nanocomposite (10) is increased. However, even in these cases, the transparency is increased and the crack generation during film thickening is repressed.

In addition, the mean diameter of the inorganic oxide nanoparticle (12a) measured by direct observation method is 2 nm or greater and 100 nm or smaller, a secondary coagulation of the inorganic oxide nanoparticle (12a) is repressed and the transparency is increased.

In addition, as the inorganic oxide nanoparticle (12a) is prepared with titanium oxide, zirconium oxide, or barium titanium acid, the refractive index of the nanocomposite (10) may be easily increased.

In addition, as the inorganic oxide nanoparticle (12a) is prepared with a rutile-type titanium oxide, the refractive index of the nanocomposite (10) may be easily increased.

In addition, in an embodiment of the present disclosure, as the surface of the inorganic oxide nanoparticle (12a) is modified by Surface Modification Method NO. 1 with the first functional group and the second functional group (12c), the surface of the inorganic oxide nanoparticle (12a) may be modified more definitely and more easily.

In addition, in an embodiment of the present disclosure, as the surface of the inorganic oxide nanoparticle (12a) is modified by Surface Modification Method NO. 2 with the first functional group and the second functional group (12c), the surface of the inorganic oxide nanoparticle (12a) may be modified more definitely and more easily.

In addition, in an embodiment of the present disclosure, as the nanocomposite (10) is prepared by Preparation Method NO. 2 (in situ polymerization method), coagulation of the inorganic oxide nanoparticle (12a) during the preparation of the nanocomposite (10) may be repressed.

In addition, as the surface light emitting device (100) according to an embodiment of the present disclosure includes the nanocomposite (10), the power efficiency, which is light emitting efficiency, is improved.

As described above, one or more of the above aspects of the present disclosure provide a high refractive index nanocomposite having excellent heat resistance and transparency and allowing for repression of a crack generation during film thickening, a method of preparing the same, and a surface light emitting device wherein the light emitting performance is improved by using the nanocomposite.

It should be understood that the exemplary embodiments described therein should be considered in a descriptive sense only and not for purposes of limitation. Descriptions of features or aspects within each embodiment should typically be considered as available for other similar features or aspects in other embodiments.

While one or more embodiments of the present disclosure have been described with reference to the figures, it will be understood by those of ordinary skill in the art that various changes in form and details may be made therein without departing from the spirit and scope of the present disclosure as defined by the following claims.

What is claimed is:

1. A nanocomposite comprising:
a matrix resin including a polyimide;
and a surface-modified inorganic oxide nanoparticle dispersed in the matrix, wherein the surface-modified inorganic oxide nanoparticle includes
an inorganic oxide nanoparticle;
a first functional group modifying a surface of the inorganic oxide nanoparticle and having an imide backbone; and
a second functional group modifying a surface of the inorganic oxide nanoparticle and binding to the matrix resin.

2. The nanocomposite of claim 1, wherein the second functional group comprises an epoxy group.

3. The nanocomposite of claim 1, wherein the vol % of the inorganic oxide nanoparticle based on the total nanocomposite is from about 30 to about 60 vol %.

4. The nanocomposite of claim 1, wherein the mean particle diameter of the inorganic oxide nanoparticle measured by direct observation method is in a range from about 2 nanometers to about 100 nanometers.

5. The nanocomposite of claim 1, wherein the inorganic oxide nanoparticle comprises at least one oxide selected from titanium oxide, zirconium oxide, and barium titanium acid.

6. The nanocomposite of claim 5, wherein the inorganic oxide nanoparticle comprises a rutile titanium oxide.

7. A method of preparing a nanocomposite comprising:
modifying a surface of an inorganic oxide nanoparticle with a silane coupling agent having an amino group, represented by General Formula 1, or a phosphate ester compound having an amino group, represented by General Formula 2;
imidizing at least a portion of the amino groups to produce an inorganic oxide nanoparticle having a surface modified with a first functional group having an imide backbone,
modifying the surface of the inorganic oxide nanoparticle with a second functional group to obtain a surface-modified inorganic oxide nanoparticle comprising the inorganic oxide nanoparticle and the first functional group and the second functional group modifying the surface of the inorganic oxide nanoparticle; and
mixing the surface-modified inorganic oxide nanoparticle with a polyamic acid and treating with heat the resulting mixture of the surface-modified inorganic oxide nanoparticle and the polyamic acid 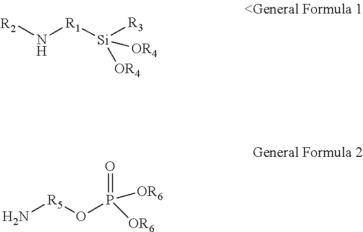
wherein,
in General Formula 1, R₁ is a substituted or unsubstituted C1 through C10 alkylene group, a substituted or unsubstituted C6 through C20 arylene group, or a substituted or unsubstituted C4 through C20 heteroarylene group, R₂ is a hydrogen atom or a substituted or unsubstituted C1 through C10 alkyl group, R₃ is a substituted or unsubstituted C1 through C10 alkyl group or a substituted or unsubstituted C1 through C10 alkoxy group, and R₄ is a substituted or unsubstituted C1 through C10 alkyl group, and
in General Formula 2, R₅ is a substituted or unsubstituted C1 through C10 alkylene group, a substituted or unsubstituted C6 through C20 arylene group, or a substituted or unsubstituted C4 through C20 heteroarylene group, and R₆ is a substituted or unsubstituted C1 through C10 alkyl group.

8. A method of preparing a nanocomposite comprising:
imidizing at least a portion of amino groups included in a silane coupling agent, represented by General Formula 1, or a phosphate ester compound, represented by General Formula 2, to obtain a silane coupling agent or a phosphate ester compound having an imide backbone;
binding the silane coupling agent or the phosphate ester compound having an imide backbone to a surface of an inorganic oxide nanoparticle to obtain an inorganic oxide nanoparticle having a surface modified with a first functional group having the imide backbone;
modifying the surface of the inorganic oxide nanoparticle with a second functional group having an epoxy group to obtain a surface-modified inorganic oxide nanoparticle comprising the inorganic oxide nanoparticle and the first functional group and the second functional group modifying the surface of the inorganic oxide nanoparticle; and
mixing the surface-modified inorganic oxide nanoparticle with a polyamic acid and treating with heat the resulting mixture of the surface-modified inorganic oxide nanoparticle and the polyamic acid 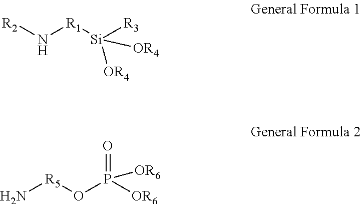
wherein
in General Formula 1, R₁ is a substituted or unsubstituted C1 through C10 alkylene group, a substituted or unsubstituted C6 through C20 arylene group, or a substituted or unsubstituted C4 through C20 heteroarylene group, R₂ is a hydrogen atom or a substituted or unsubstituted C1 through C10 alkyl group, R₃ is a substituted or unsubstituted C1 through C10 alkyl group or a substituted or unsubstituted C1 through C10 alkoxy group, and R₄ is a substituted or unsubstituted C1 through C10 alkyl group, and
in General Formula 2, R₅ is a substituted or unsubstituted C1 through C10 alkylene group, a substituted or unsubstituted C6 through C20 arylene group, or a substituted or unsubstituted C4 through C20 heteroarylene group, and R₆ is a substituted or unsubstituted C1 through C10 alkyl group.

9. A method of preparing a nanocomposite comprising:
modifying a surface of an inorganic oxide nanoparticle with a silane coupling agent having an amino group, represented by General Formula 1, or a phosphate ester compound having an amino group, represented by General Formula 2;
imidizing at least a portion of the amino groups to produce an inorganic oxide nanoparticle having a surface modified with a first functional group having an imide backbone;
modifying the surface of the inorganic oxide nanoparticle with a second functional group having an epoxy group to produce a surface-modified inorganic oxide nanoparticle comprising the inorganic oxide nanoparticle and a first functional group and a second functional group modifying the surface of the inorganic oxide nanoparticle; and
mixing the surface-modified inorganic oxide nanoparticle with a diamine and an acid dianhydride and reacting the diamine and the acid dianhydride to produce a mixture of the surface-modified inorganic oxide nanoparticle and a polyamic acid, and treating with heat the resulting mixture 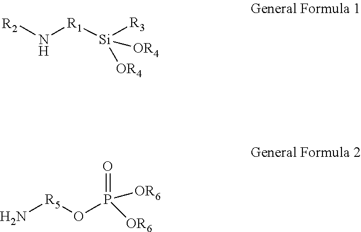
wherein
in General Formula 1, R₁ is a substituted or unsubstituted C1 through C10 alkylene group, a substituted or unsubstituted C6 through C20 arylene group, or a substituted or unsubstituted C4 through C20 heteroarylene group, R₂ is a hydrogen atom or a substituted or unsubstituted C1 through C10 alkyl group, R₃ is a substituted or unsubstituted C1 through C10 alkyl group or a substituted or unsubstituted C1 through C10 alkoxy group, and R₄ is a substituted or unsubstituted C1 through C10 alkyl group, and
in General Formula 2, R₅ is a substituted or unsubstituted C1 through C10 alkylene group, a substituted or unsubstituted C6 through C20 arylene group, or a substituted or unsubstituted C4 through C20 heteroarylene group, and R₆ is a substituted or unsubstituted C1 through C10 alkyl group.

10. A method of preparing a nanocomposite comprising:
imidizing at least a portion of amino groups included in a silane coupling agent, represented by General Formula 1, or a phosphate ester compound, represented by General Formula 2, to obtain a silane coupling agent or a phosphate ester compound having an imide backbone;
binding the silane coupling agent or the phosphate ester compound having an imide backbone to a surface of an inorganic oxide nanoparticle to obtain an inorganic oxide nanoparticle having a surface modified with a first functional group having an imide backbone;
modifying the surface of the inorganic oxide nanoparticle with a second functional group having an epoxy group to obtain a surface-modified inorganic oxide nanoparticle comprising the inorganic oxide nanoparticle and a first functional group and a second functional group modifying the surface of the inorganic oxide nanoparticle; and
mixing the surface-modified inorganic oxide nanoparticle with a diamine and an acid dianhydride and reacting the diamine and the acid dianhydride to produce a mixture of the surface-modified inorganic oxide nanoparticle and a polyamic acid, and treating with heat the resulting mixture 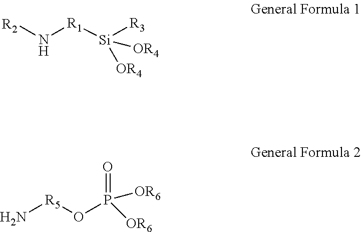
wherein
in General Formula 1, R₁ is a substituted or unsubstituted C1 through C10 alkylene group, a substituted or unsubstituted C6 through C20 arylene group, or a substituted or unsubstituted C4 through C20 heteroarylene group, R₂ is a hydrogen atom or a substituted or unsubstituted C1 through C10 alkyl group, R₃ is a substituted or unsubstituted C1 through C10 alkyl group or a substituted or unsubstituted C1 through C10 alkoxy group, and R₄ is a substituted or unsubstituted C1 through C10 alkyl group, and
in General Formula 2, R₅ is a substituted or unsubstituted C1 through C10 alkylene group, a substituted or unsubstituted C6 through C20 arylene group, or a substituted or unsubstituted C4 through C20 heteroarylene group, and R₆ is a substituted or unsubstituted C1 through C10 alkyl group.

11. A surface light emitting device comprising:
a translucent substrate wherein a transparent substrate of the translucent substrate is covered by a covering layer comprising the nanocomposite of claim 1;
a transparent conductive film laminated on the translucent substrate; and
an organic electroluminescent layer laminated on the transparent conductive film.

12. The surface light emitting device of claim 11, wherein the translucent substrate comprises the transparent substrate having an embossed surface and the covering layer covers the embossed surface of the transparent substrate.

13. The surface light emitting device of claim 11, wherein the covering layer comprises the nanocomposite and a scattering particle dispersed in the nanocomposite; and
the translucent substrate comprises the transparent substrate having a flat surface and the covering layer covers the flat surface of the transparent substrate.

14. The surface light emitting device of claim 11, wherein the translucent substrate comprises the transparent substrate having an embossed surface and the covering layer covers the embossed surface of the transparent substrate; and
the covering layer comprises the nanocomposite and a scattering particle dispersed in the nanocomposite.
